(19) United States
(12) Patent Application Publication
(10) Pub. No.: US 2025/0386574 A1
(43) Pub. Date: Dec. 18, 2025

(54) Semiconductor Structures and Methods of Forming Same

(71) Applicant: Taiwan Semiconductor Manufacturing Company, Ltd., Hsin-Chu (TW)

(72) Inventors: Chun-Yang LU, Taoyuan City (TW); Tzu-Yu CHEN, New Taipei City (TW); Szu-Ying CHEN, Hsinchu (TW); Liang-Yin CHEN, Hsinchu City (TW)

(21) Appl. No.: 18/923,033

(22) Filed: Oct. 22, 2024

Related U.S. Application Data
(60) Provisional application No. 63/659,547, filed on Jun. 13, 2024.

(51) Int. Cl. H01L 29/66; H01L 21/8234; H01L 27/088; H01L 29/06; H01L 29/08; H01L 29/423; H01L 29/775; H01L 29/786

(52) U.S. Cl. CPC H10D 64/017; H10D 30/014; H10D 30/43; H10D 30/6735; H10D 30/6757; H10D 62/121; H10D 62/151; H10D 84/0128; H10D 84/013; H10D 84/038; H10D 84/83

(57) ABSTRACT

A method includes providing a workpiece including a fin-shaped structure including a stack of alternating channel layers and sacrificial layers, forming a dummy gate structure over a channel region of the fin-shaped structure, forming a source/drain recess in a source/drain region of the fin-shaped structure, selectively removing the sacrificial layers in the channel region to release the channel layers as channel members, performing a hydrogen treatment to the workpiece, after performing the hydrogen treatment, depositing a dummy layer around the channel members, forming a source/drain feature over the source/drain region, and replacing the dummy gate structure and the dummy layer with a metal gate structure.

### PRIORITY DATA

This application claims priority to U.S. Provisional Patent Application No. 63/659,547, filed Jun. 13, 2024, which is hereby incorporated herein by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Gate-all-around (GAA) transistors are examples of multi-gate devices that have become popular and promising candidates for high performance and low leakage applications. A GAA transistor has a gate structure that can extend, partially or fully, around a channel region to provide access to the channel region on two or more sides.

However, despite having many desirable features, multi-gate device fabrication has continued to face challenges as a result of the ongoing scaling down of semiconductor IC dimensions. Thus, existing techniques have not proved entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor structure, according to one or more aspects of the present disclosure.

FIGS. 2, 3, 4, 5, 6, 7A, 8A, 9A, 11, 12, 13, 14, 15, 16A, 17A, 18A, 19, 20, 21, 22, and 23A illustrate fragmentary cross-sectional views of an exemplary semiconductor structure during various fabrication stages in the method of FIG. 1, according to one or more aspects of the present disclosure.

FIGS. 7B, 8B, 9B, 16B, and 17B illustrate enlarged views of a portion of the exemplary semiconductor structure in FIGS. 7A, 8A, 9A, 16A, and 17A, respectively, according to one or more aspects of the present disclosure.

FIGS. 9C, 17C, 18B, 18C, 23B, and 23C illustrate enlarged fragmentary cross-sectional views of a portion of the exemplary semiconductor structure in FIGS. 9A, 17A, 18A, 18A, 23A, and 23A, respectively, according to one or more aspects of the present disclosure.

FIGS. 10A and 10B illustrate schematic diagrams of a portion of the exemplary semiconductor structure in FIG. 9A, according to one or more aspects of the present disclosure.

FIG. 24 illustrates a flowchart of a method for forming a semiconductor structure, according to one or more aspects of the present disclosure.

FIGS. 25A, 26, 27, 28, 29A, 30A, 30D, 31, 32, and 33 illustrate fragmentary cross-sectional views of an exemplary semiconductor structure during various fabrication stages in the method of FIG. 24, according to one or more aspects of the present disclosure.

FIGS. 25B, 25C, 29B, 29C, 30B, and 30C illustrate enlarged views of a portion of the exemplary semiconductor structure in FIGS. 25A, 25A, 29A, 29A, 30A or 30D, and 30A or 30D, respectively, according to one or more aspects of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

GAA transistors may also be referred to as nanosheet transistors or nanowire transistors. They can be either n-type or p-type. GAA transistors may have channel regions disposed in nanowire channel members, bar-shaped channel members, nanosheet channel members, nanostructure channel members, bridge-shaped channel members, and/or other suitable channel configurations. Variants of GAA transistors, such as fish-bone structures or fork-sheet structures, have been proposed to reduce cell dimensions. In a fish-bone structure or a fork-sheet structure, adjacent stacks of channel members may be divided by a dielectric wall (or a dielectric fin). The dielectric wall usually has a height substantially equal to or greater than that of the topmost channel members or that of the source/drain features. The dielectric wall and dielectric features over the dielectric wall may be used to isolate adjacent source/drain contacts.

In some existing technologies, the formation of GAA transistors includes forming a number of channel layers interleaved by a number of sacrificial layers and performing a channel release process to selectively remove the sacrificial layers to release the channel layers as channel members. The channel layers and the sacrificial layers may include different compositions. However, the sacrificial layers may intermix with the channel layers to form an intermixing compound. The intermixing compound may be oxidized and may not be fully removed during the channel release process, thereby disadvantageously impacting overall performance of the GAA transistors. While existing techniques are generally adequate for their intended purposes, they are not satisfactory in all aspects.

The present disclosure provides methods for forming a semiconductor device such as a GAA transistor. In an example process, a fin-shaped structure with channel layers and sacrificial layers is formed over a substrate. After formation of a dummy gate stack over a channel region of the fin-shaped structure, at least one gate spacer is formed over the dummy gate stack. Source/drain regions of the fin-shaped structure are recessed. The sacrificial layers are selectively removed to release the channel layers as channel members. In an embodiment, a hydrogen treatment is performed to remove residues (e.g., an oxidized intermixing layer) over the channel members. Further processes are then performed to finish the fabrication of the GAA transistor. In another embodiment where residues are negligible, instead of performing the hydrogen treatment, an oxygen treatment may be performed to form an oxide layer over the channel members to protect the channel layers during the following processes. In yet another embodiment, both the hydrogen treatment and the oxygen treatment are performed. By performing the hydrogen treatment and/or the oxygen treatment, residues of the sacrificial layers on the channel members may be reduced or mitigated, surfaces and corners of the channel members may be modified (e.g., smoothened, rounded), and/or the channel members may be protected by the oxide layer in the following processes, thus overall performance of the semiconductor device may be improved.

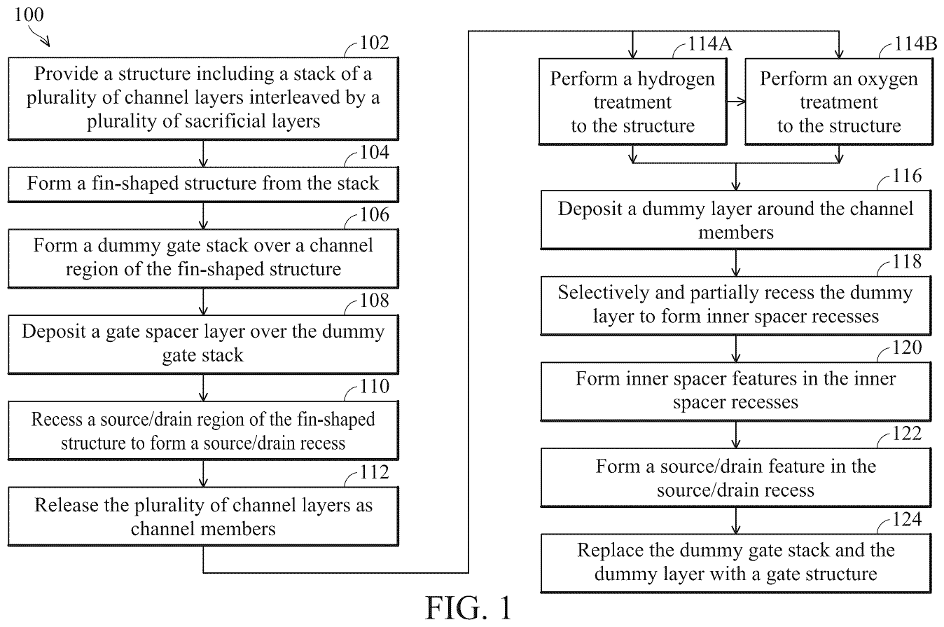

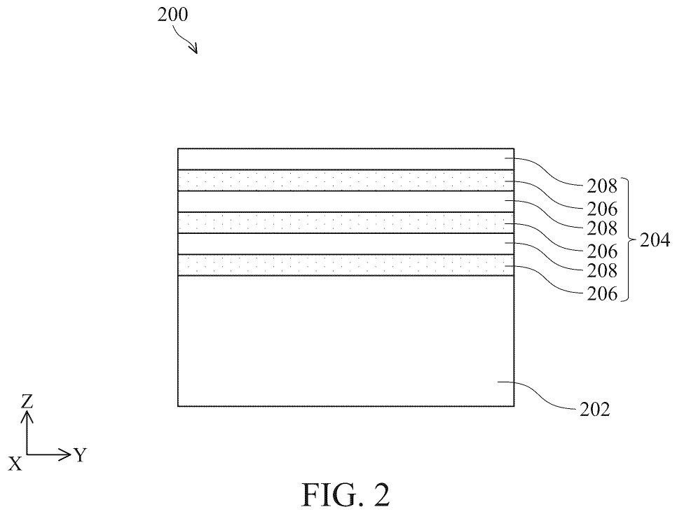

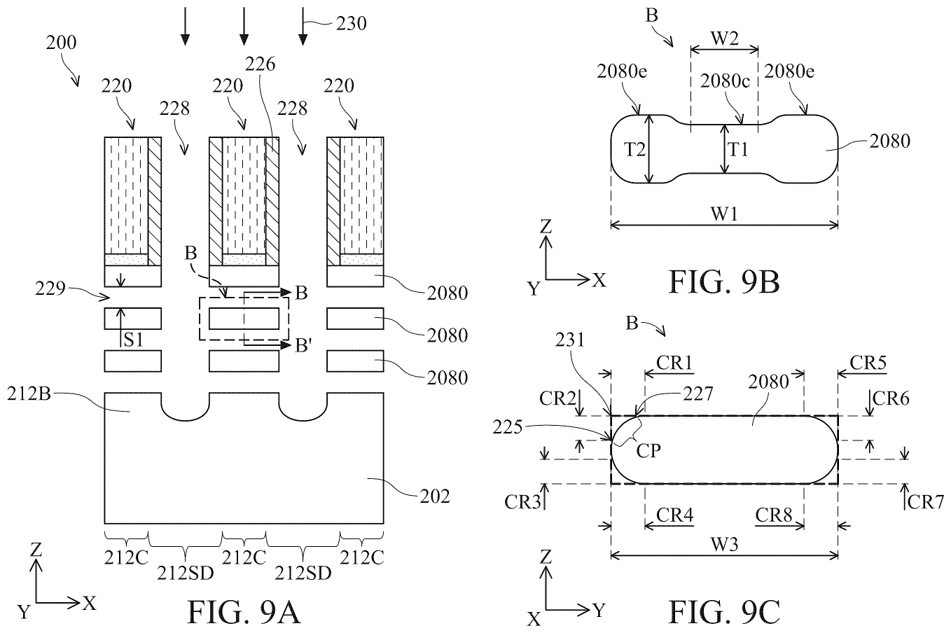

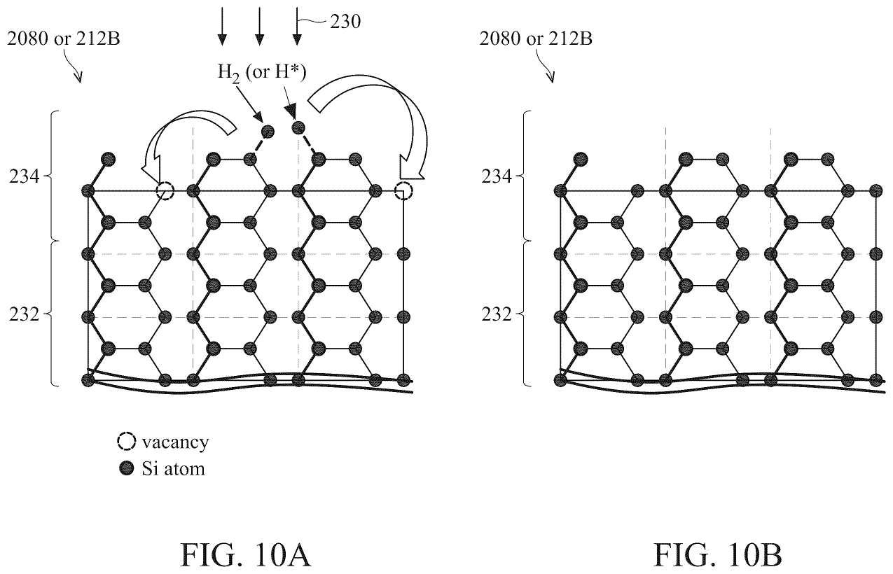

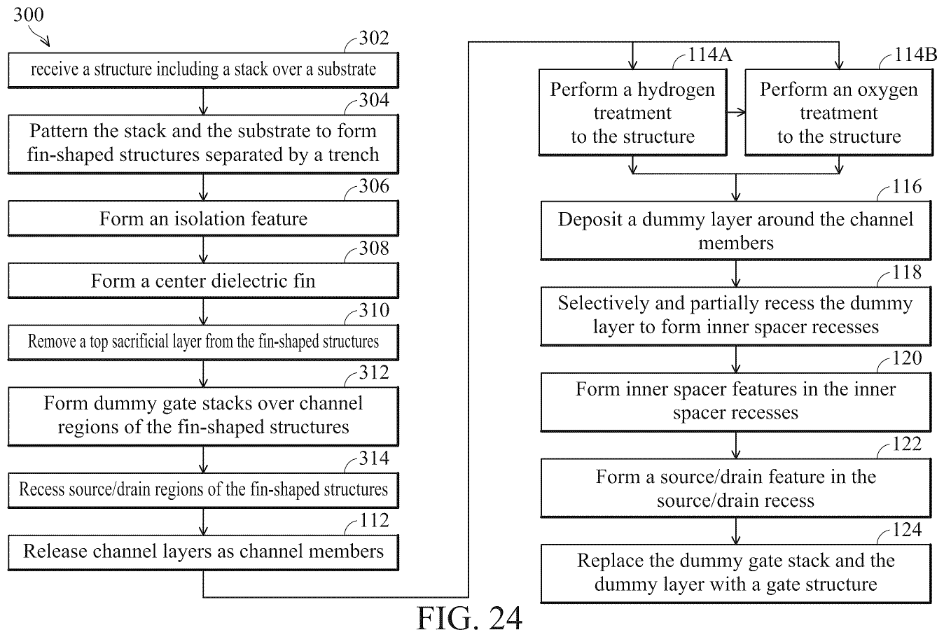

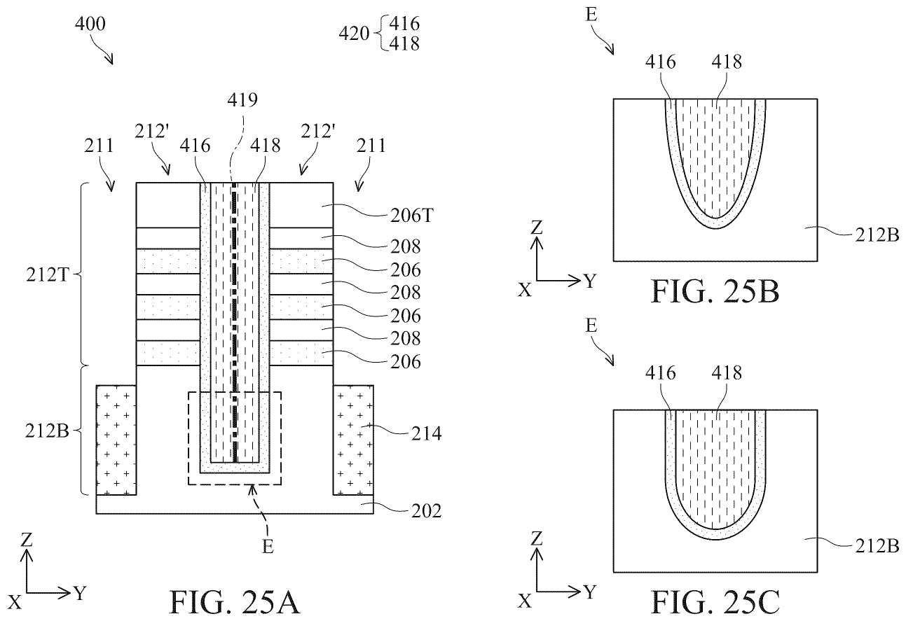

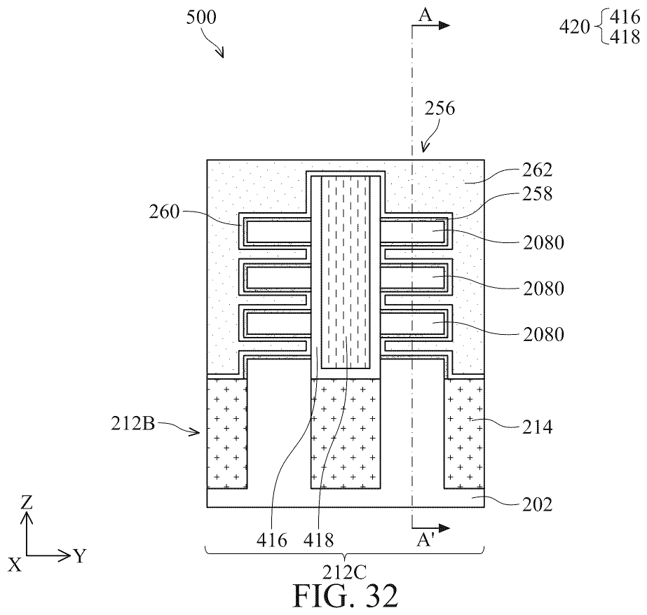

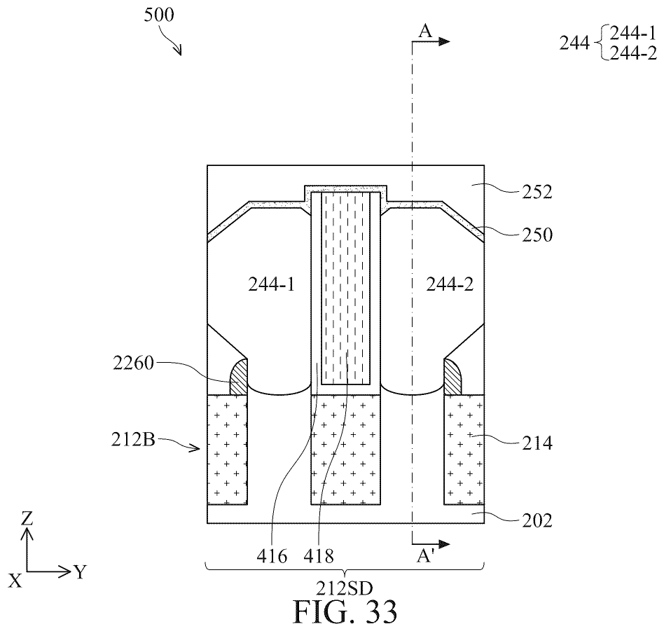

The various aspects of the present disclosure will now be described in more detail with reference to the figures. In that regard, FIG. 1 is a flowchart illustrating method 100 of forming a semiconductor structure according to embodiments of the present disclosure. Method 100 is described below in conjunction with FIGS. 2-23C. FIGS. 2-9C and 11-23C are fragmentary cross-sectional views of a structure 200 at different stages of fabrication according to embodiments of method 100 in FIG. 1. FIGS. 10A and 10B illustrate schematic diagrams of a portion of the structure 200 in FIG. 9. FIG. 24 is a flowchart illustrating method 300 of forming a semiconductor structure according to embodiments of the present disclosure. Method 300 is described below in conjunction with FIGS. 25A-33. FIGS. 25A-31 are fragmentary cross-sectional views of a structure 400 at different stages of fabrication according to embodiments of method 300 in FIG. 24. FIGS. 32-33 are fragmentary cross-sectional views of an alternative structure 500 at different stages of fabrication according to embodiments of method 300 in FIG. 24. Method 100 and method 300 are merely examples and are not intended to limit the present disclosure to what is explicitly illustrated in method 100 and method 300. Additional steps can be provided before, during and after method 100 (or method 300), and some steps described can be replaced, eliminated, or moved around for additional embodiments of method 100 (or method 300). Not all steps are described herein in detail for reasons of simplicity. Because the structure 200 (or 400 or 500) will be fabricated into a semiconductor structure or a semiconductor device, the structure 200 (or 400 or 500) may be referred to herein as a semiconductor structure 200 (or 400 or 500) or a semiconductor device 200 (or 400 or 500) as the context requires. For avoidance of doubts, the X, Y and Z directions in FIGS. 2-9C, 11-23C, and 25A-33 are perpendicular to one another and are used consistently throughout the present disclosure. Throughout the present disclosure, like reference numerals denote like features unless otherwise excepted. That is, material properties and comparisons thereof for various numbered elements described in association with a method or a figure should apply to the same numbered elements described in association with a different method or a different figure.

Further, the semiconductor structures disclosed herein may include various other devices and features, such as other types of devices including additional transistors, bipolar junction transistors, resistors, capacitors, inductors, diodes, fuses, SRAM and/or other logic circuits, etc., but are simplified for a better understanding of the inventive concepts of the present disclosure. In some embodiments, the exemplary devices include a plurality of semiconductor devices (e.g., transistors), including n-type GAA transistors, p-type GAA transistors, PFETs, NFETs, etc., which may be interconnected.

Referring to FIGS. 1 and 2, method 100 includes a block 102 where a structure 200 is provided. As shown in FIG. 2, the structure 200 includes a substrate 202 and a stack 204 of alternating semiconductor layers formed over the substrate 202. In some embodiments, the substrate 202 may be a semiconductor substrate such as a silicon (Si) substrate. The substrate 202 may include various doping configurations depending on design requirements as is known in the art. In embodiments where the semiconductor device is p-type, an n-type doping profile (i.e., an n-type well or n-well) may be formed on the substrate 202. In some implementations, the n-type dopant for forming the n-type well may include phosphorus (P), arsenic (As), or antimony (Sb). In embodiments where the semiconductor device is n-type, a p-type doping profile (i.e., a p-type well or p-well) may be formed on the substrate 202. In some implementations, the p-type dopant for forming the p-type well may include boron (B) or gallium (Ga). The suitable doping may include ion implantation of dopants and/or diffusion processes. The substrate 202 may also include other semiconductors such as germanium (Ge), silicon carbide (SiC), silicon germanium (SiGe), germanium tin (GeSn), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features.

In some embodiments, the stack 204 over the substrate 202 includes channel layers 208 of a first semiconductor composition interleaved by sacrificial layers 206 of a second semiconductor composition. It can also be said that the sacrificial layers 206 are interleaved by the channel layers 208. The first and second semiconductor composition may be different. In some embodiments, the sacrificial layers 206 include silicon germanium (SiGe) or germanium tin (GeSn) and the channel layers 208 include silicon (Si). It is noted that three (3) layers of the sacrificial layers 206 and three (3) layers of the channel layers 208 are alternately arranged as illustrated in FIG. 2, which is for illustrative purposes only and not intended to be limiting beyond what is specifically recited in the claims. It can be appreciated that any number of epitaxial layers may be formed in the stack 204. The number of layers depends on the desired number of channel members for the semiconductor device 200. In some embodiments, the number of channel layers 208 is between 2 and 10.

The sacrificial layers 206 and channel layers 208 in the stack 204 may be deposited using a molecular beam epitaxy (MBE) process, a vapor phase epitaxy (VPE) process, and/or other suitable epitaxial growth processes. As stated above, in at least some examples, the sacrificial layers 206 include an epitaxially grown silicon germanium (SiGe) layer and the channel layers 208 include an epitaxially grown silicon (Si) layer. In some embodiments, the sacrificial layers 206 and the channel layers 208 are substantially dopant-free (i.e., having an extrinsic dopant concentration from about 0 atoms/cm³ to about 1×10¹⁷ atoms/cm³), where for example, no intentional doping is performed during the epitaxial growth processes for the stack 204.

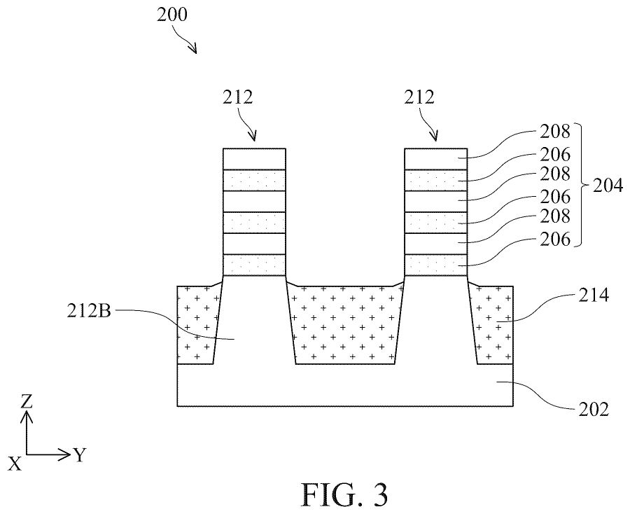

Referring to FIGS. 1 and 3, method 100 includes a block 104 where a fin-shaped structure 212 (also referred to as an active region 212) is formed from the stack 204 and the substrate 202. To pattern the stack 204, a hard mask layer may be deposited over the stack 204 to form an etch mask. The hard mask layer may be a single layer or a multi-layer. For example, the hard mask layer may include a pad oxide layer and a pad nitride layer disposed over the pad oxide layer. The fin-shaped structure 212 may be patterned from the stack 204 and the substrate 202 using a lithography process and an etch process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods. As shown in FIG. 3, the etch process at block 104 forms trenches extending vertically through the stack 204 and a portion of the substrate 202. The trenches define the fin-shaped structures 212. In some implementations, double-patterning or multi-patterning processes may be used to define fin-shaped structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shaped structure 212 by etching the stack 204 and a portion of the substrate 202. As shown in FIG. 3, the fin-shaped structure 212 that includes the sacrificial layers 206 and the channel layers 208 extends vertically along the Z direction and lengthwise along the X direction. As shown in FIG. 3, the fin-shaped structure 212 includes a base fin structure 212B patterned from the substrate 202. The patterned stack 204, including the sacrificial layers 206 and the channel layers 208, is disposed directly over the base fin structure 212B.

An isolation feature 214 is formed adjacent to the fin-shaped structure 212. In some embodiments represented in FIG. 3, the isolation feature 214 is disposed on sidewalls of the base fin structure 212B. In some embodiments, the isolation feature 214 may be formed in the trenches to isolate the fin-shaped structures 212 from a neighboring fin-shaped structure 212. The isolation feature 214 may also be referred to as a shallow trench isolation (STI) feature 214. By way of example, in some embodiments, a dielectric layer is first deposited over the substrate 202, filling the trenches with the dielectric layer. In some embodiments, the dielectric layer may include silicon oxide, silicon oxynitride, fluorine-doped silicate glass (FSG), a low-k dielectric, combinations thereof, and/or other suitable materials. In various examples, the dielectric layer may be deposited by a chemical vapor deposition (CVD) process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the STI feature 214 shown in FIG. 3. The fin-shaped structure 212 rises above the STI feature 214 after the recessing, while the base fin structure 212B is embedded or buried in the isolation feature 214.

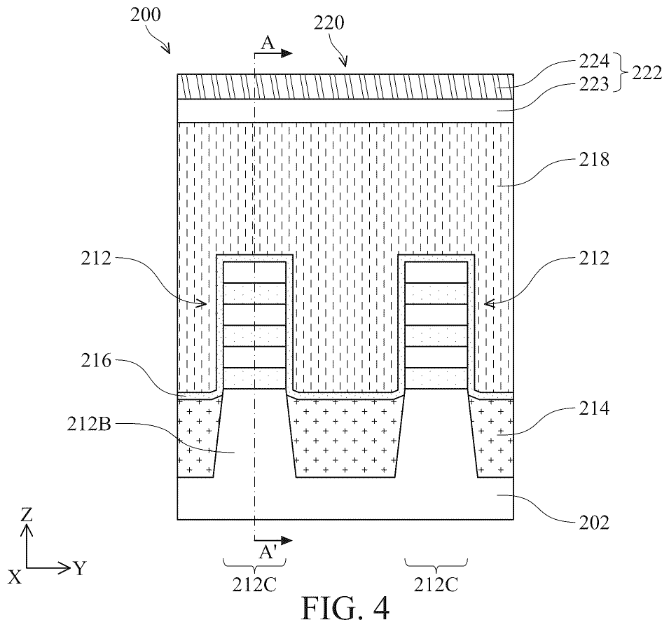

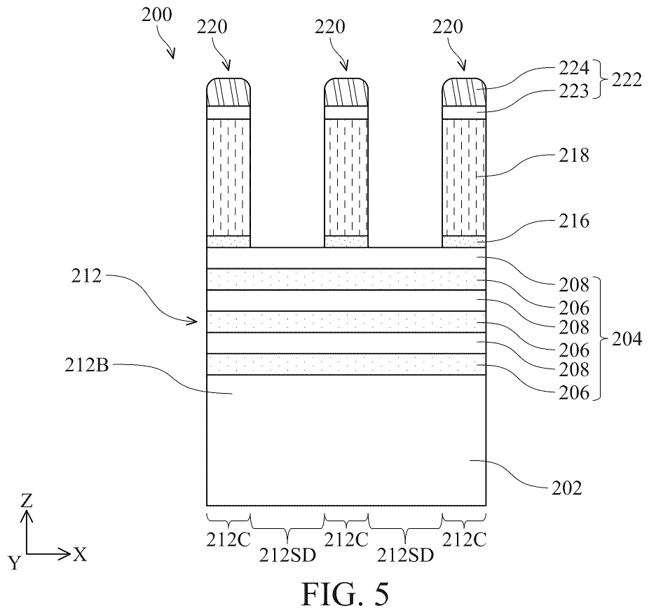

Referring to FIGS. 1, 4, and 5, method 100 includes a block 106 where a dummy gate stack 220 is formed over a channel region 212C of the fin-shaped structure 212. FIG. 5 illustrates a fragmentary cross-section view of the structure 200 taken along line A-A′ as in FIG. 4. In some embodiments, a gate replacement process (or gate-last process) is adopted where the dummy gate stack 220 (shown in FIGS. 4 and 5) serves as a placeholder to undergo various processes and is to be removed and replaced by a functional gate structure. Other processes and configuration are possible. In some embodiments illustrated in FIG. 5, the dummy gate stack 220 is formed over the fin-shaped structure 212 and the fin-shaped structure 212 may be divided into channel regions 212C underlying the dummy gate stacks 220 and source/drain regions 212SD that do not underlie the dummy gate stacks 220. The channel regions 212C are adjacent to the source/drain regions 212SD. As shown in FIG. 5, the channel region 212C is disposed between two source/drain regions 212SD along the X direction.

The formation of the dummy gate stack 220 may include deposition of layers in the dummy gate stack 220 and patterning of these layers. Referring to FIG. 4, a dummy dielectric layer 216, a dummy electrode layer 218, and a gate-top hard mask layer 222 may be blanketly deposited over the structure 200. In some embodiments, the dummy dielectric layer 216 may be formed on the fin-shaped structure 212 using a chemical vapor deposition (CVD) process, an atomic layer deposition (ALD) process, an oxygen plasma oxidation process, or other suitable processes. In some instances, the dummy dielectric layer 216 may include silicon oxide. Thereafter, the dummy electrode layer 218 may be deposited over the dummy dielectric layer 216 using a CVD process, an ALD process, or other suitable processes. In some instances, the dummy electrode layer 218 may include polysilicon. For patterning purposes, the gate-top hard mask layer 222 may be deposited on the dummy electrode layer 218 using a CVD process, an ALD process, or other suitable processes. The gate-top hard mask layer 222, the dummy electrode layer 218 and the dummy dielectric layer 216 may then be patterned to form the dummy gate stack 220, as shown in FIG. 5. For example, the patterning process may include a lithography process (e.g., photolithography or e-beam lithography) and an etching process. The lithography process may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The photolithography process forms a patterned photoresist layer. The patterned photoresist layer is then applied as an etch mask in the etching process to pattern the gate-top hard mask layer 222, the dummy electrode layer 218 and the dummy dielectric layer 216. In some embodiments, the etching process may include dry etching (e.g., RIE etching), wet etching, and/or other etching methods. In some embodiments, the gate-top hard mask layer 222 may include a silicon oxide layer 223 and a silicon nitride layer 224 over the silicon oxide layer 223. As shown in FIG. 5, the dummy gate stack 220 is patterned such that it is only disposed over the channel region 212C, not disposed over the source/drain region 212SD.

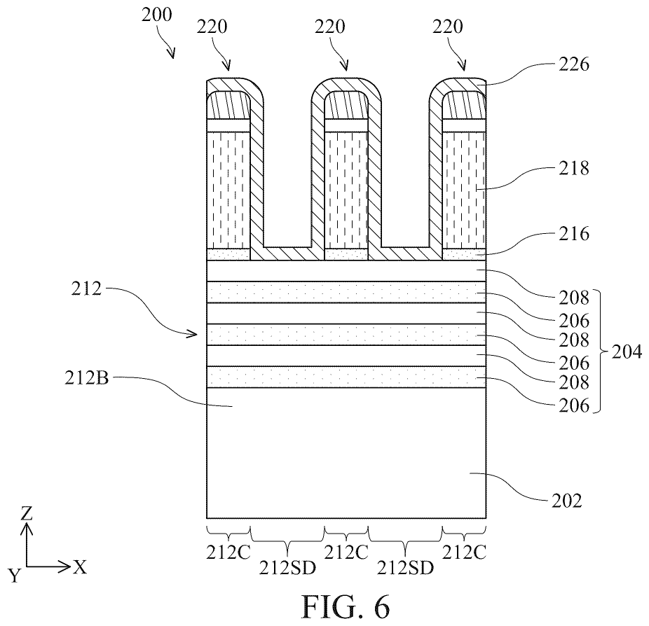

Referring to FIGS. 1 and 6, method 100 includes a block 108 where a gate spacer layer 226 is deposited over the structure 200, including over the dummy gate stack 220. In some embodiments, the gate spacer layer 226 is deposited conformally over the structure 200, including over top surfaces and sidewalls of the dummy gate stack 220. The term “conformally” may be used herein for ease of description of a layer having substantially uniform thickness over various regions. The gate spacer layer 226 may be a single layer or a multi-layer. The at least one layer in the gate spacer layer 226 may include silicon carbonitride, silicon oxycarbide, silicon oxycarbonitride, or silicon nitride. The gate spacer layer 226 may be deposited over the dummy gate stack 220 using processes such as, a CVD process, a subatmospheric CVD (SACVD) process, an ALD process, or other suitable process.

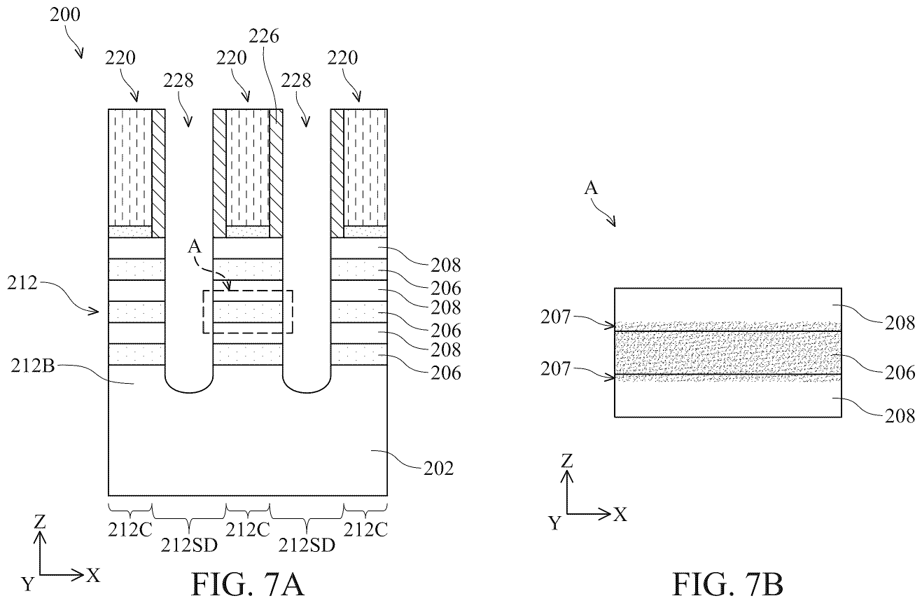

Referring to FIGS. 1 and 7A-7B, method 100 includes a block 110 where a source/drain region 212SD of the fin-shaped structure 212 is anisotropically recessed to form a source/drain trench 228. FIG. 7B illustrates an enlarged view of a portion A in FIG. 7A. The anisotropic etch may include a dry etch or a suitable etch process that etches the gate spacer layer 226, the source/drain regions 212SD and a portion of the substrate 202 below the source/drain regions 212SD. The resulting source/drain trench 228 extends vertically through the depth of the stack 204 and partially into the substrate 202. An example dry etch process for block 110 may implement an oxygen-containing gas, a fluorine-containing gas (e.g., CF₄, SF₆, CH₂F₂, CHF₃, C₄F₈, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As illustrated in FIG. 7A, the source/drain regions 212SD of the fin-shaped structure 212 are recessed to expose sidewalls of the sacrificial layers 206 and the channel layers 208. Because the source/drain trenches 228 extend below the stack 204 into the substrate 202, the source/drain trenches 228 include bottom surfaces and lower sidewalls defined in the substrate 202.

Referring to FIG. 7B, the channel layers 208 (or the base fin structure 212B) may include intermixing regions 207 where components (e.g., SiGe) of the neighboring sacrificial layer 206 penetrate or diffuse into. In some embodiments, the sacrificial layer 206 includes SiGe, the channel layer 208 and the base fin structure 212B include Si, and the intermixing region 207 includes a mixture of SiGe and Si. Concentrations of components (e.g., SiGe) of the sacrificial layer 206 may gradually decrease in the intermixing region 207 in the direction from the sacrificial layer 206 toward the channel layer 208 (or the base fin structure 212B). Concentrations of components (e.g., Si) of the channel layers 208 (or the base fin structure 212B) may gradually increase in the intermixing region 207 in the direction from the sacrificial layer 206 toward the channel layer 208 (or the base fin structure 212B). The intermixing region 207 may have a thickness of about 0.1 nm to about 2 nm.

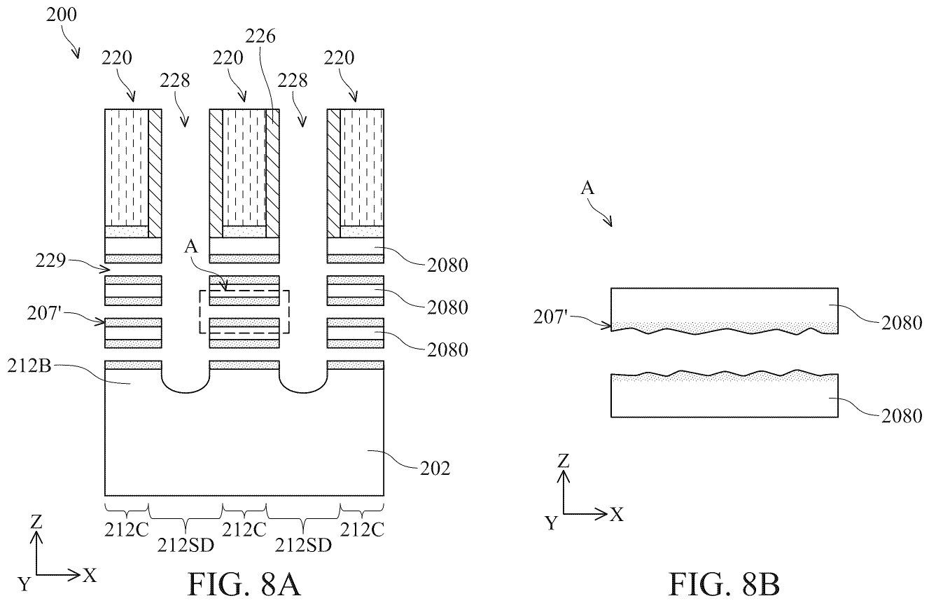

Referring to FIGS. 1 and 8A-8B, method 100 includes a block 112 where the plurality of channel layers 208 in the channel regions 212C are released as channel members 2080. FIG. 8B illustrates an enlarged view of a portion A in FIG. 8A. After the formation of the source/drain trench 228, the sacrificial layers 206 interleaving the channel layers 208 in the channel region 212C are selectively removed. The selective removal of the sacrificial layers 206 releases the channel layers 208 (shown in FIG. 7A) to form channel members 2080 shown in FIG. 8A. The selective removal of the sacrificial layers 206 forms spaces 229 between adjacent channel members 2080. The selective removal of the sacrificial layers 206 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture). Depending on the design, the channel members 2080 may take form of nanowires, nanosheets, or other nanostructures. In this embodiment, the selective removal of the sacrificial layers 206 exposes the intermixing region 207, and the exposed intermixing region 207 may react with the environment (e.g., ambient gas) and/or etchant of the etching process, thereby forming a residue 207′ (or a residue layer 207′) on the channel members 2080 and the base fin structure 212B. In embodiments where the intermixing regions 207 include silicon germanium, the residue 207′ may include a germanium-containing composition. For example, the residue 207′ includes germanium oxide GeOx, where x is in a range between about 1 and 2. If left untreated, the residue 207′ may impact profiles of interfaces (to be described below) between source/drain features and the channel members 2080 and may disadvantageously impact overall performance of the structure 200.

Referring to FIGS. 1 and 9A-9C, method 100 further includes a block 114A where a hydrogen treatment 230 is performed. FIG. 9B illustrates an enlarged view of a portion B in FIG. 9A. FIG. 9C illustrates an enlarged cross-sectional view of the portion B taken along line B-B′.

The hydrogen treatment 230 may remove the residue 207′ (as in FIGS. 8A-8B). After the hydrogen treatment 230, the spaces 229 may each have a height S1 of about 6 nm to about 8 nm. The hydrogen treatment 230 may use a process gas including hydrogen alone or hydrogen in combination with other gases, such as inert gases (e.g., argon (Ar)). In some embodiments, the process gas of the hydrogen treatment 230 excludes oxygen. A ratio of H₂ to the inert gases may be about 1% to less than 100%. The hydrogen treatment 230 may be at a pressure of about 10 mtorr to about 500 torr, alternatively of about 100 mtorr to about 5 torr.

During the performing of the hydrogen treatment 230, hydrogen (e.g., hydrogen plasma or the hydrogen gas) may react with the oxidized germanium GeOx (e.g., germanium dioxide GeO₂, germanium monoxide GeO) in the residue 207′ to form germanium hydride (GeH₄), which is a gas at the process condition and may be removed by the process gas. The hydrogen treatment 230 may remove more than about 70% of the residue 207′ (or more than about 70% of GeOx in the residue 207′). Water (H₂O) may be formed in the hydrogen treatment 230 and removed by the process gas. In some embodiments, the following reaction mechanisms (1) to (3) may apply. H* stands for hydrogen radical or atomic hydrogen.

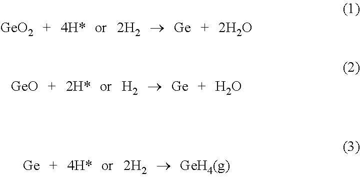

The hydrogen treatment 230 may include a plasma process or an annealing process with hydrogen. In some embodiments, the plasma process with hydrogen plasma including hydrogen radical (H*) is performed. The plasma process may involve a plasma source that includes capacitively coupled plasma (CCP), radio-frequency (RF), inductively coupled plasma (ICP), micro-wave, or combinations thereof. The hydrogen plasma process may be performed at a temperature between about 300° C. to about 650° C. A plasma source power may be about 0.1 kW to about 7.0 kW. In some other embodiments, the annealing process with hydrogen is performed. The annealing process may include a rapid thermal anneal (RTA), a spike rapid thermal anneal (RTA), or a microsecond anneal. The annealing process may be performed at a temperature of about 600° C. to about 900° C. for a time duration of about 1 second to about 6,000 seconds.

In some embodiments, the hydrogen treatment 230 restructures (e.g., recrystallizes) exposed surfaces of the channel members 2080 and the base fin structure 212B. The hydrogen treatment 230 may repair dangling bonds, such as silicon dangling bonds on the exposed surfaces. FIGS. 10A and 10B illustrate schematic diagrams of the restructuring process of an exposed surface of the channel members 2080 or the base fin structure 212B. It is understood that FIGS. 10A and 10B merely represent an example, and the restructuring process may involve other structures and structure changes. Referring to FIG. 10A, the channel members 2080 or the base fin structure 212B include an inner region 232 and a surface region 234. Crystal structures in the inner regions 232 are more stable and complete than crystal structures in the surface region 234. In the depicted embodiment, the surface region 234 includes dangling bonds as illustrated by dashed lines and vacancies as illustrated by the dashed circles. During the hydrogen treatment 230, hydrogen atoms attack silicon atoms connected by the dangling bonds and occupy positions of those silicon atoms. Those silicon atoms may take the vacancies, and the hydrogen atoms may be released from the dangling bonds by heating during the hydrogen treatment 230 or heating in the following processes. The releasing of the hydrogen atoms may be at a temperature of about 100° C. to about 400° C. The crystal structures in the surface region 234 become more stable and more similar to the crystal structures in the inner regions 232 after the hydrogen treatment 230. As the dangling bonds are removed, the smoothness of surfaces of the channel layers 2080 and the base fin structure 212B is improved, gate control of the channel layers 2080 may be improved. In some embodiments, surface roughness of the surfaces of the channel layers 2080 and the base fin structure 212B may be represented by a line width roughness (LWR). Performing the hydrogen treatment 230 reduces the LWR of the surfaces of the channel layers 2080 and the base fin structure 212B to about 0.3 nm to about 0.4 nm.

Because of the restructuring, corners of the channel members 2080 and the base fin structure 212B may be rounded. Referring to FIG. 9B, after the hydrogen treatment 230, the channel member 2080 may have a dog-bone shaped profile. A center portion 2080c of the channel member 2080 may have a thickness T1 less than a thickness T2 of end portions 2080e of the channel member 2080. This may result from exposing to uneven distribution of hydrogen atoms. T1 and T2 are about 4 nm to about 7 nm. The channel member 2080 may have a width W1 along the X-direction. The center portion 2080c may have substantially flat top and bottom surfaces and have a width W2 along the X-direction. A ratio of W2 to W1 may be about 30% to about 90%, alternatively about 40% to about 80%. Corners of the end portions 2080e and junctions of the center portion 2080c and the end portions 2080e may be rounded or smoothened as depicted. Corner rounding may improve gate control of the channel members 2080, thus improving overall performance of the structure 200.

Referring to FIG. 9C, when viewed from the X-direction, the channel member 2080 may have a shape of a rectangle with rounded corners or a racetrack. The channel member 2080 may have a width W3 of about 8 nm to about 50 nm along the Y-direction. The channel member 2080 may have rounded corners. Each of the rounded corners may have a curvature profile (e.g., CP as depicted) having two end points (e.g., 225 and 227) as depicted. The illustrated dashed rectangle represents an imaginary profile of the channel member 2080 with no rounded corners and having right angle corners (e.g., 231). A corner rounding dimension herein refers to a distance between an end point (225 or 227) of an curvature profile (e.g., CP) and a corresponding right angle corner (or a most adjacent right angle corner, e.g., 231) of the dashed rectangle. In the depicted embodiment, the corner rounding dimensions include CR1-CR8. The corner rounding dimension may be about 2.5 nm to about 3.5 nm. If the corner rounding dimension is too small, the surfaces of the channel layers 2080 and the base fin structure 212B may be too rough. If the corner rounding dimension is too large, surface area of the channel member 2080 may be too small and gate control of the channel member 2080 may be impacted.

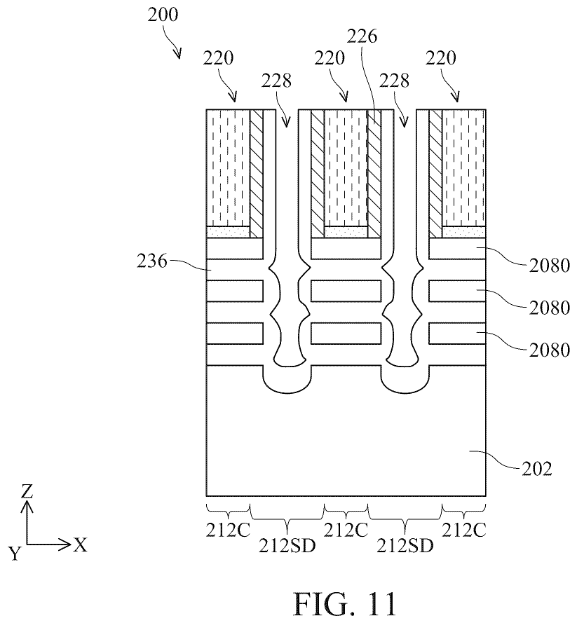

Referring to FIGS. 1 and 11, method 100 includes a block 116 where a dummy layer 236 is deposited around the channel members 2080 and over the source/drain trench 228. The dummy layer 236 may include a dielectric material. The dielectric material may include an oxide, a nitride, a carbide, or a combination thereof. Examples of the dielectric material may include silicon oxide, SiCO, SiN, SiCN, and aluminum oxide (e.g., Al₂O₃). In some embodiments, the dummy layer 236 includes silicon oxide and/or aluminum oxide. The dummy layer 236 may be deposited using plasma enhanced chemical vapor deposition (PECVD), an flowable CVD (FCVD), PEALD, ALD, or a rapid thermal oxidation (RTO) process. As shown in FIG. 11, the dummy layer 236 fills the space 229 (as in FIG. 9A) among the channel members 2080 and covers end sidewalls of the channel members 2080. Additionally, the dummy layer 236 is in direct contact with a sidewall of the gate spacer layer 226 and a top surface of the substrate 202 or the base fin structure 212B.

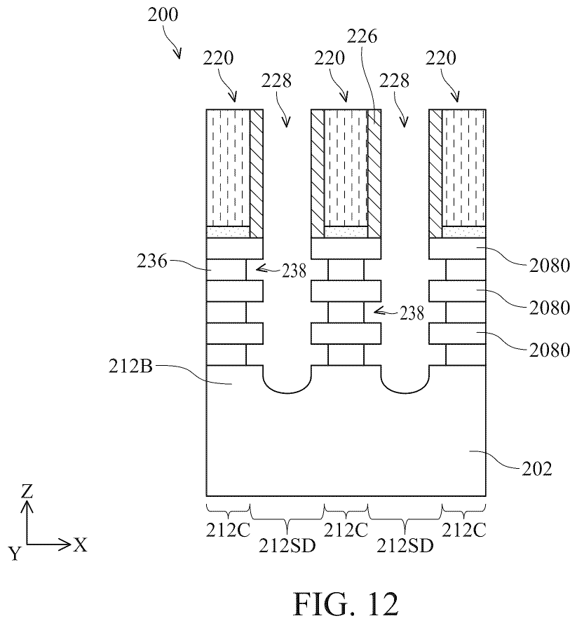

Referring to FIGS. 1 and 12, method 100 includes a block 118 where the dummy layer 236 is selectively and partially recessed to form inner spacer recesses 238 while the gate spacer layer 226, the dummy gate stack 220, the exposed portion of the substrate 202 or the base fin structure 212B, and the channel layers 208 are substantially unetched. In an embodiment where the channel layers 208 consist essentially of silicon (Si) and the dummy layer 236 is formed of silicon oxide, the selective recess of the dummy layer 236 may be performed using a selective wet etch process or a selective dry etch process. An example selective dry etching process may include use of carbon tetrafluoride (CF₄), nitrogen trifluoride (NF₃), hydrogen (H₂), or a mixture thereof. An example selective wet etching process may include use of hydrofluoric acid, ammonium fluoride, or a mixture thereof.

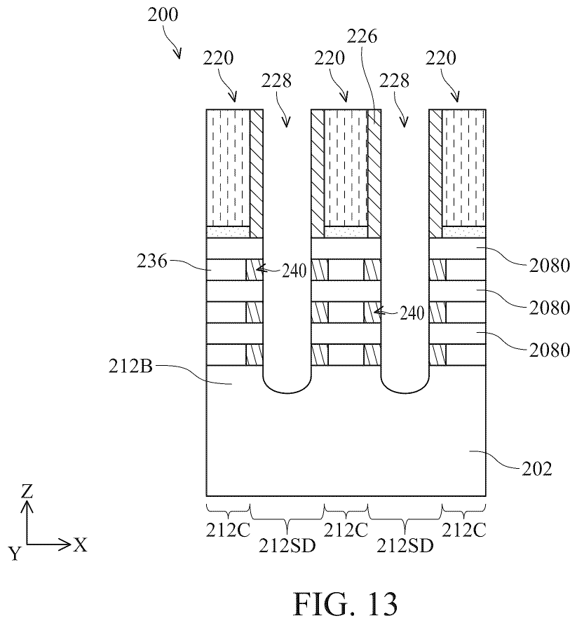

Referring to FIGS. 1 and 13, method 100 includes a block 120 where inner spacer features 240 are formed in the inner spacer recesses 238. While not shown explicitly, operation at block 120 may include deposition of inner spacer material over the structure 200, and etching back the inner spacer material to form the inner spacer features 240 in the inner spacer recesses 238 (shown in FIG. 13). After the inner spacer recesses 238 are formed, an inner spacer material is deposited over the structure 200, including over the inner spacer recesses 238. The inner spacer material may include metal oxides, silicon oxide, silicon oxycarbonitride, silicon nitride, silicon oxynitride, carbon-rich silicon carbonitride, or a low-k dielectric material. The metal oxides may include aluminum oxide, zirconium oxide, tantalum oxide, yttrium oxide, titanium oxide, lanthanum oxide, or other suitable metal oxide. While not explicitly shown, the inner spacer material may be a single layer or a multilayer. In some implementations, the inner spacer material may be deposited using CVD, PECVD, SACVD, ALD or other suitable methods. The inner spacer material is deposited into the inner spacer recesses 238 as well as over the sidewalls of the channel members 2080 exposed in the source/drain trenches 228. Referring to FIG. 13, the deposited inner spacer material is then etched back to remove the inner spacer material from the sidewalls of the channel members 2080 to form the inner spacer features 240 in the inner spacer recesses 238. In the depicted embodiment, outer sidewalls of the inner spacer features 240 may extend beyond sidewalls of the neighboring channel members 2080.

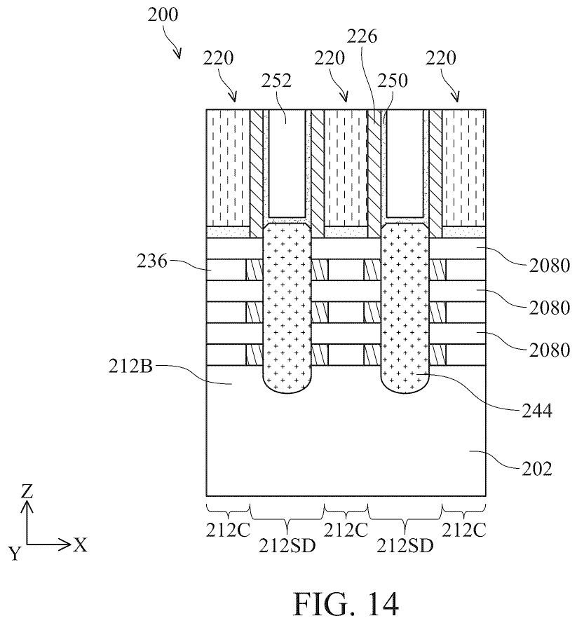

Referring to FIGS. 1 and 14, method 100 includes a block 122 where a source/drain feature 244 is formed over the source/drain region 212SD. While not explicitly shown, before any of the epitaxial layers are formed, method 100 may include a cleaning process to clean surfaces of the structure 200. The cleaning process may include a dry clean, a wet clean, or a combination thereof. In some examples, the wet clean may include use of standard clean 1 (RCA SC-1, a mixture of deionized (DI) water, ammonium hydroxide, and hydrogen peroxide), standard clean 2 (RCA SC-2, a mixture of DI water, hydrochloric acid, and hydrogen peroxide), SPM (a sulfuric peroxide mixture), and or hydrofluoric acid for oxide removal. The dry clean process may include helium (He) and hydrogen (H₂) treatment. The hydrogen treatment may convert silicon on the surface to silane (SiH₄), which may be pumped out for removal.

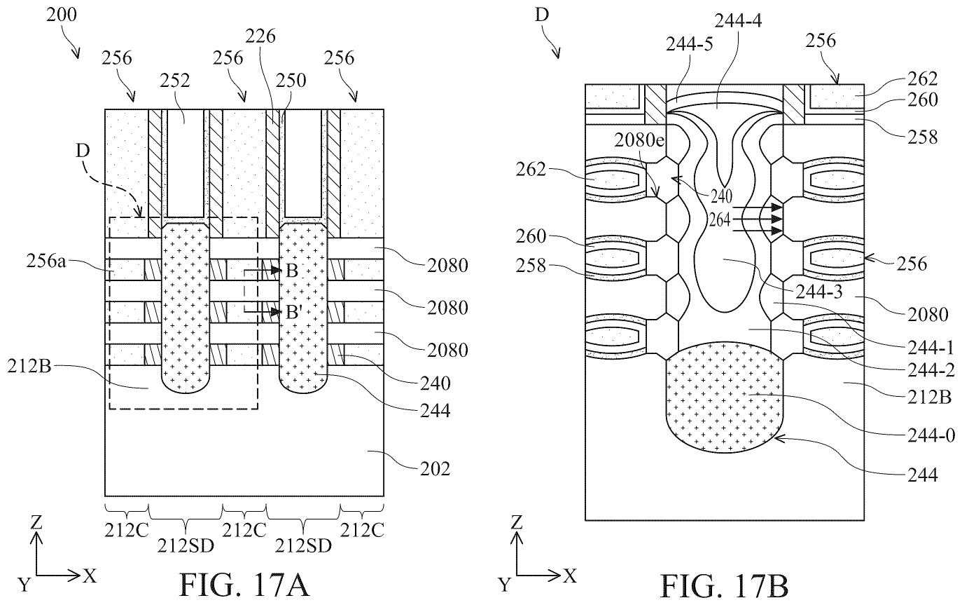

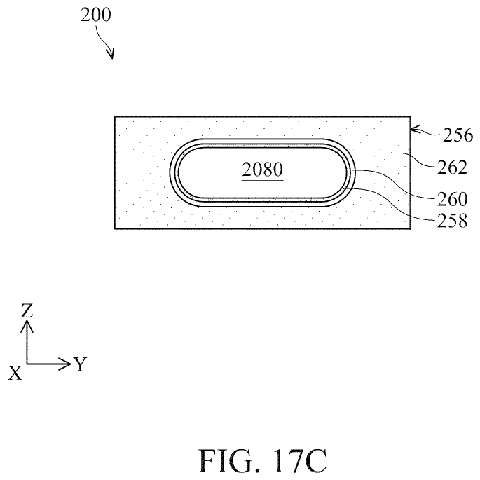

Source/drain feature(s) 244 may refer to a source or a drain, individually or collectively dependent upon the context. The source/drain features 244 are coupled to the channel regions 212C. Each of the source/drain features 244 may be epitaxially and selectively formed from exposed semiconductor surfaces by using an epitaxial process, such as vapor phase epitaxy (VPE), ultrahigh vacuum chemical vapor deposition (UHV-CVD), molecular-beam epitaxy (MBE), and/or other suitable processes. Example n-type source/drain features may include silicon, phosphorus-doped silicon, arsenic-doped silicon, antimony-doped silicon, or other suitable material and may be in-situ doped during the epitaxial process by introducing an n-type dopant, such as phosphorus, arsenic, or antimony, or ex-situ doped using a junction implant process. Example p-type source/drain features may include germanium, gallium-doped silicon germanium, boron-doped silicon germanium, or other suitable material and may be in-situ doped during the epitaxial process by introducing a p-type dopant, such as boron or gallium, or ex-situ doped using a junction implant process. In some embodiments, each of the n-type source/drain features and the p-type source/drain features may include multiple semiconductor layers with different doping concentrations, such as layers 244-0 through 244-5 in FIG. 17B. The n-type source/drain features and the p-type source/drain features may be formed in any suitable sequential orders.

Operations at block 122 may further include deposition of a contact etch stop layer (CESL) 250 over the source/drain features 244 and deposition of an interlayer dielectric (ILD) layer 252 over the CESL 250. Referring to FIG. 14, the CESL 250 is deposited over the structure 200, including over the source/drain feature 244. The CESL 250 may include silicon nitride or aluminum nitride. In some implementations, the CESL 250 may be deposited using CVD or ALD. The ILD layer 252 is then deposited over the CESL 250. In some embodiments, the ILD layer 252 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 252 may be deposited using CVD, FCVD, spin-on coating, or a suitable deposition technique. After the deposition of the ILD layer 252, the structure 200 may be planarized by a planarization process to expose the dummy gate stack 220. For example, the planarization process may include a chemical mechanical planarization (CMP) process. Exposure of the dummy gate stack 220 allows the removal of the dummy gate stack 220.

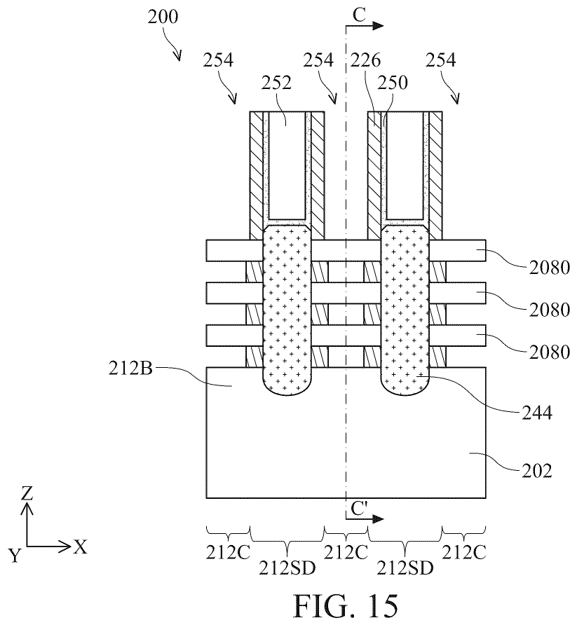

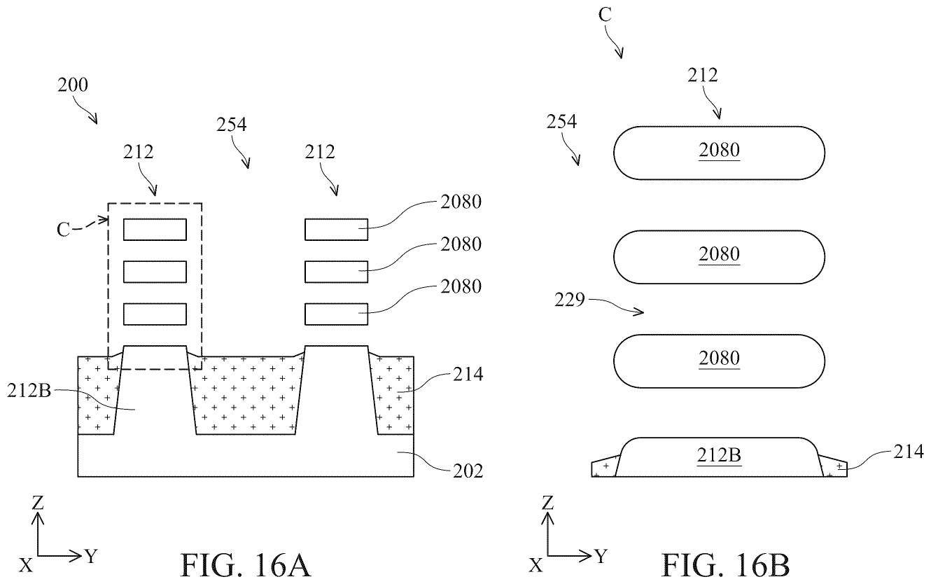

Referring to FIGS. 1 and 15-17C, method 100 includes a block 124 where the dummy gate stack 220 and the dummy layer 236 are replaced with a gate structure 256. FIG. 16A illustrates a fragmentary cross-section view of the structure 200 taken along line C-C′ as in FIG. 15. FIG. 16B illustrates an enlarged view of a portion C in FIG. 16A. FIG. 17B illustrates an enlarged view of a portion D in FIG. 17A. FIG. 17C illustrates an enlarged cross-section view of a portion of the structure 200 taken along line B-B′. Operations at block 124 may include removal of the dummy gate stack 220 (shown in FIGS. 15-16B), removal of the dummy layer 236 (shown in FIGS. 15-16B), and deposition of the gate structure 256 to wrap around each of the channel members 2080 (shown in FIGS. 17A-17C).

Referring to FIGS. 15-16B, the dummy gate stack 220 is removed. The removal of the dummy gate stack 220 may include one or more etching processes that are selective to the material of the dummy gate stack 220. For example, the removal of the dummy gate stack 220 may be performed using a selective wet etch, a selective dry etch, or a combination thereof that is selective to the dummy gate stack 220.

After the removal of the dummy gate stack 220, sidewalls of the channel members 2080 and the dummy layer 236 in the channel region 212C are exposed. Referring to FIGS. 15-16B, a separate etch process may be performed to selectively remove the dummy layer 236 in the channel region 212C. For example, a selective wet etch process or a selective dry etch process may be performed to remove the dummy layer 236. An example selective wet etch process may include use of diluted hydrofluoric acid (DHF) or a mixture of hydrofluoric acid (HF) and, ammonium fluoride (NH₄F). An example selective dry etch process may include use of anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof. After the selective removal of the dummy layer 236, the channel members 2080 in the channel region 212C are once again exposed as shown in FIGS. 15-16B. In the depicted embodiment, surfaces of the channel layers 2080 and the base fin structure 212B may have rounded corners as described above. The selective removal of the dummy layer 236 forms a gate trench 254 that includes spaces 229 between adjacent channel members 2080.

Referring to FIGS. 17A-17C, a gate structure 256 is formed to wrap around each of released as channel members 2080. After the release of the channel members 2080, the gate structure 256 is formed to wrap around each of the channel members 2080. As shown in FIGS. 17B-17C, the gate structure 256 includes an interfacial layer 258 interfacing the channel members 2080 and the base fin structure 212B in the channel region 212C, a gate dielectric layer 260 over the interfacial layer 258, and a gate electrode layer 262 over the gate dielectric layer 260. The interfacial layer 258 may include a dielectric material such as silicon oxide, hafnium silicate, or silicon oxynitride. The interfacial layer 258 may be formed by chemical oxidation, thermal oxidation, atomic layer deposition (ALD), chemical vapor deposition (CVD), and/or other suitable method. The gate dielectric layer 260 may include a high-k dielectric material, such as hafnium oxide. Alternatively, the gate dielectric layer 260 may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. The gate dielectric layer 260 may be formed by ALD, physical vapor deposition (PVD), CVD, oxidation, and/or other suitable methods. Referring to FIG. 17C, the gate dielectric layer 260 and the interfacial layer 258 may have similar rounded corners as the channel layer 2080. Outer surfaces of the gate dielectric layer 260 and the interfacial layer 258 may have a profile of a rectangle with rounded corners or a racetrack in the cross-sectional view.

The gate electrode layer 262 of the gate structure 256 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer 262 may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer 262 may be formed by ALD, PVD, CVD, e-beam evaporation, or other suitable process. In various embodiments, a CMP process may be performed to remove excessive metal, thereby providing a substantially planar top surface of the gate structure. The gate structure 256 includes portions 256a that interpose between the channel members 2080 in the channel region 212C.

Referring to FIG. 17B, the channel members 2080 have the dog-bone shaped profile as described above. A top surface of the topmost channel member may be substantially flat. The inner spacer features 240 may include a first portion vertically sandwiched between the end portions 2080e of the channel members 2080 and a second portion embedded in the source/drain feature 244. The source/drain feature 244 may include more than one layers (e.g., epitaxial semiconductor layers), such as layers 244-0, 244-1, 244-2, 244-3, 244-4, and 244-5.

Without being limited by theory, diffusivity of p-type dopants (e.g., boron) and n-type dopants (e.g., phosphorus) in different materials (e.g., silicon, germanium) are different. For example, a p-type dopant may diffuse more slowly into Ge than into Si and an n-type dopant may diffuse faster into Ge than into Si. When there is Ge residue (e.g., in the residue 207′) on surfaces of the channel member, dopants may diffuse from the source/drain feature into the channel member unevenly along the interface between the source/drain feature and the channel member. This may result in different concentration profiles of a p-type dopant and an n-type dopant at a corresponding junction of the source/drain feature and the channel member. Thus, interfaces between a p-type source/drain feature and adjacent channel members may have different profiles from interfaces between an n-type source/drain feature and adjacent channel members. In the embodiments of the present disclosure, because of the removal of the residue 207′, Ge on the channel members 2080 is negligible. Thus, diffusivity and junction push 264 of p-type dopants (or the n-type dopants) from the p-type (or n-type) source/drain feature 244 to the channel members 2080 may be substantially uniform along interfaces of the p-type (or n-type) source/drain feature 244 and the channel members 2080. A uniform p-type dopant junction push may reduce resistance of the channel members 2080. A uniform n-type dopant junction push may reduce current leakage between the gate structure 256 and nearby contacts (e.g., a source/drain contact electrically connected to the source/drain feature 244). The interfaces of a p-type source/drain feature 244 and the channel members 2080 and the interfaces of an n-type source/drain feature 244 and the channel members 2080 may have similar flat profiles as depicted in FIG. 17B.

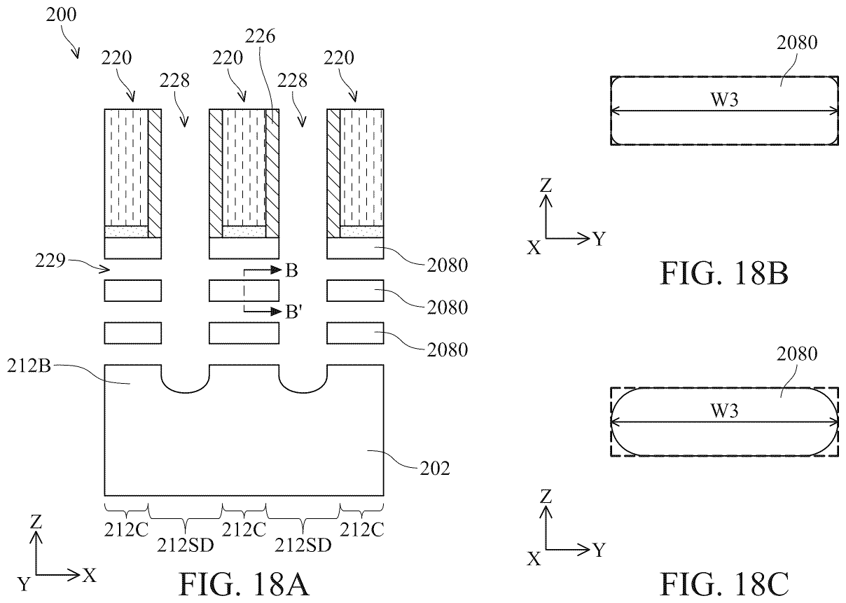

In one alternative embodiment represented by FIG. 1 and FIGS. 18A-18B, after performing operations at blocks 102-112 of method 100, instead of performing operations at block 114A, operations at block 114B are performed. FIG. 18A illustrates a fragmentary cross-sectional view of the structure 200 upon completion of operations at block 112. FIG. 18B illustrates an enlarged cross-sectional view of a portion of the structure 200 taken along line B-B′ as in FIG. 18A according to different aspects of the present disclosure. With respect to FIGS. 18A-18B, upon completion of operations at block 112, in some embodiments, residue 207′ on the channel members 2080 is negligible. In such embodiments, corners of the channel members 2080 and the base fin structure 212B are only slightly rounded from the operations at block 112 as depicted in FIG. 18B. The corner rounding dimension of the channel members 2080 may be equal to or less than about 2 nm, for example, about 0.5 nm to about 2 nm. A width of the channel member 2080 along the Y-direction may be W3 as described above.

In another alternative embodiment represented by FIG. 1, FIGS. 18A and 18C, method 100 includes performing both operations at block 114A and operations at block 114B. FIG. 18A illustrates a fragmentary cross-sectional view of the structure 200 upon completion of operations at block 114A, FIG. 18C illustrates an enlarged cross-sectional view of a portion of the structure 200 taken along line B-B′ as in FIG. 18A according to different aspects of the present disclosure. In such embodiments, corners of the channel members 2080 and the base fin structure 212B are rounded by the hydrogen treatment as described above with respect to FIGS. 8A-10B.

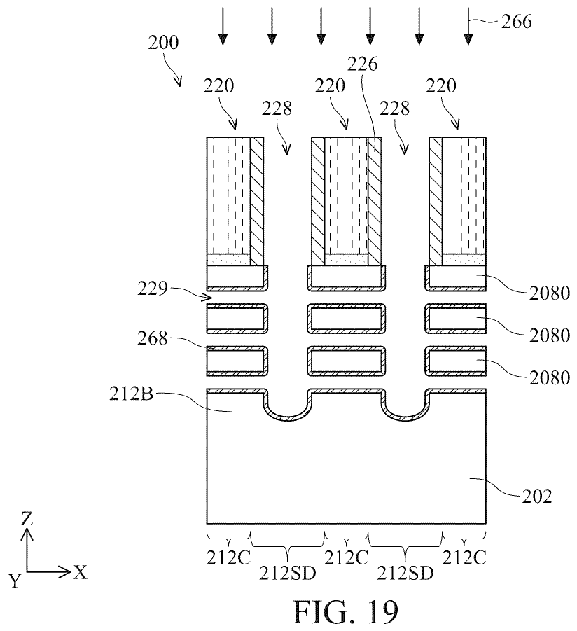

Referring now to FIGS. 1 and 19, operations at block 114B include performing an oxygen treatment 266 to the structure 200. As described above, the oxygen treatment 266 may be performed with or without performing the hydrogen treatment 230.

The oxygen treatment 266 may oxidize the exposed surfaces of the channel members 2080 and the base fin structure 212B to form an oxide layer 268. The oxide layer 268 may protect (e.g., prevent impurities from entering) the channel members 2080 and the base fin structure 212B in the following processes. The oxide layer 268 may have various thicknesses at different locations on the exposed surfaces. Thicknesses of the oxide layer 268 may be in a range of about 0.1 nm to about 3 nm, alternatively about 0.5 nm to about 2 nm. In some embodiments, the thicknesses of the oxide layer 268 has a uniformity value of less than about 1%, alternatively less than about 0.5%. The uniformity is referred to as the consistency of the thickness distribution of the oxide layer 268 on the exposed surfaces of the channel members 2080 and the base fin structure 212B. A uniformity value of zero means that the thickness of the oxide layer 268 at each location is identical. A higher uniformity value means a worse uniformity. The oxide layer 268 may include silicon dioxide at a concentration greater than about 95%, alternatively greater than about 99%.

In some embodiments, the oxygen treatment 266 may include an oxygen plasma process with oxygen plasma including molecular radical and ion or atomic radical and ion is performed. The oxygen plasma process may use a process gas including oxygen (O₂) alone or oxygen in combination with other gases, such as hydrogen and inert gases (e.g., Ar). A concentration of oxygen in the process gas may be about 0.1% to less than 100%. Components of the process gas may be in a radical form. In some embodiments, the process gas includes inert gases at metastable state, which may be generated by a remote plasma source (RPS) a decoupled plasma source (DPS), or other plasma sources. The inert gases at metastable state may be molecular radical and ion or atomic radical and ion. During the oxygen plasma process, energy may be transferred from the inert gases at metastable state to the oxygen to form oxygen radical (O*), reducing amount of thermal energy to form the oxide layer 268, thus reducing temperature for the oxygen plasma process. The inert gases at metastable state may extend lifetime of the oxygen radical and improve the uniformity of the oxide layer 268. In some embodiments, the process gas includes hydrogen radical (H*), which may attack oxygen to form oxygen radical. The plasma process may involve a plasma source that includes capacitively coupled plasma (CCP), radio-frequency (RF), inductively coupled plasma (ICP), micro-wave, or combinations thereof. The oxygen plasma process may be at a temperature between about 300° C. to about 650° C., at a pressure of about 10 mtorr to about 760 torr, alternatively of about 10 mtorr to about 500 torr, for a time duration of about 1 second to about 6,000 seconds. A plasma source power may be about 0.1 kW to about 7.0 kW. In the oxygen plasma process, the following reaction mechanism (4) may apply. O* stands for oxygen radical or atomic oxygen.

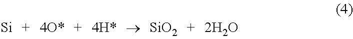

Thicknesses of the oxide layer 268, the uniformity thereof, and the concentration of silicon dioxide in the oxide layer 268 may be flexible by tuning various process parameters related to the plasma process. Examples of the process parameters include a ratio of H* to O* and a ratio of inert gases (e.g., Ar*) to O* in the process gas. In some embodiments, increasing the ratio of H* to O* increases thickness of the oxide layer 268, the uniformity value thereof, and the concentration of silicon dioxide in the oxide layer 268. In some embodiments, increasing the ratio of inert gases (e.g., Ar) to oxygen reduces the uniformity value of the thickness of the oxide layer 268 and increases the concentration of silicon dioxide in the oxide layer 268, which means that the uniformity and the quality of the oxide layer 268 are improved by adding inert gases to the process gas.

In some embodiments, the oxygen treatment 266 may include an annealing process. The annealing process may include a rapid thermal anneal (RTA), a spike rapid thermal anneal (RTA), or a microsecond anneal. The annealing process may be conducted in a furnace. The annealing process may be at a temperature of about 100° C. to about 900° C., alternatively about 600° C. to about 900° C., at a pressure of about 10 mtorr to about 760 torr, alternatively of about 10 mtorr to about 500 torr, for a time duration of about 1 second to about 6,000 seconds. The process gas of the annealing process may include steam (e.g., water vapor) and/or oxygen and may further includes hydrogen. The steam may generate oxygen and hydrogen under the process conditions. In some embodiments, a ratio of hydrogen (including hydrogen generated from the steam) to oxygen (including oxygen generated from the steam) is about 1% to about 50%, alternatively about 1% to about 40%. A concentration of oxygen in the process gas may be about 0.1% to less than 100%. The oxygen (including oxygen generated from the steam) may react with silicon in the channel members 2080 to form silicon oxide. In such embodiments, the following reaction mechanism (5) may apply.

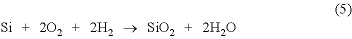

Thicknesses of the oxide layer 268, the uniformity thereof, and the concentration of silicon dioxide in the oxide layer 268 may be flexible by tuning various process parameters of the annealing process. Examples of the process parameters include the ratio of hydrogen to oxygen, a flow rate of the process gas, and pressure of the process. In some embodiments, increasing the ratio of hydrogen to oxygen increases thicknesses of the oxide layer 268 and the uniformity value thereof. In some embodiments, increasing the flow rate of the process gas increases thicknesses of the oxide layer 268 and reduces the uniformity value thereof, which means that the uniformity the oxide layer 268 is improved. In some embodiments, increasing the pressure of the process increases the thicknesses of the oxide layer 268.

In some embodiments, method 100 further includes, prior to performing operations at block 114B (e.g., the oxygen treatment 226), performing a plasma enhanced ALD (PEALD) process at a temperature lower than 400° C. In such embodiments, the PEALD process forms a sub oxide layer (not separately labeled) on the exposed surfaces of the channel members 2080 and the base fin structure 212B, and the oxide layer 268 is formed over the sub oxide layer. The oxide layer 268 may be denser, include a higher SiO₂ concentration, and have a lower etch rate in a wet etching as compared to the sub oxide layer.

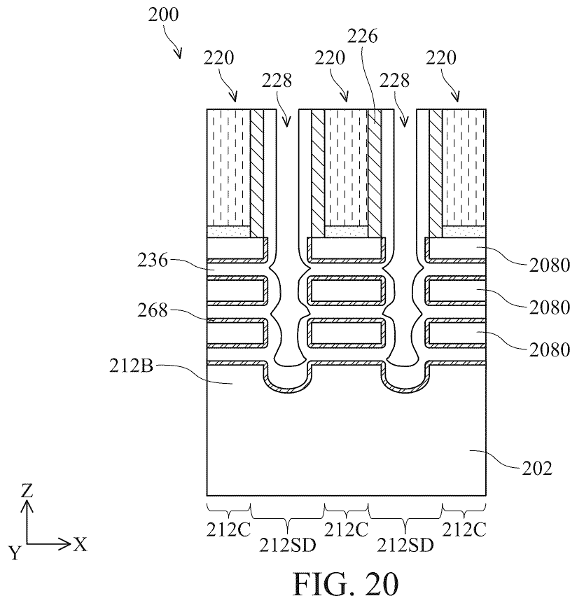

Referring to FIGS. 1 and 20, method 100 proceeds to block 116 as described above. Differences from the embodiments in FIG. 11 include that, in embodiments represented by FIG. 20, the dummy layer 236 is deposited over the oxide layer 268.

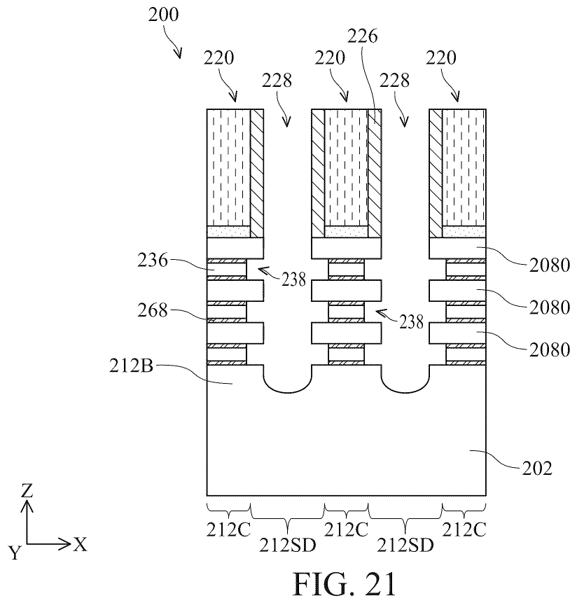

Referring to FIGS. 1 and 21, method 100 proceeds to block 118 as described above. Differences from the embodiments in FIG. 12 include the follows. As depicted in FIG. 21, besides the dummy layer 236, the oxide layer 268 is selectively and partially recessed to form the inner spacer recesses 238. The selective recess of the oxide layer 268 may be performed using a same or different selective wet etch process or a selective dry etch process as compared to the selective recess of the dummy layer 236.

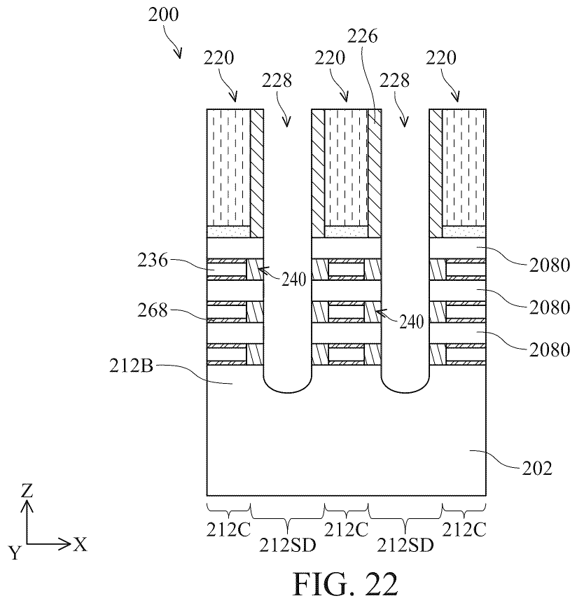

Referring to FIGS. 1 and 22, method 100 proceeds to block 120 as described above. Differences from the embodiments in FIG. 13 include that, the inner spacer features 240 depicted in FIG. 22 are also in direct contact with the oxide layer 268.

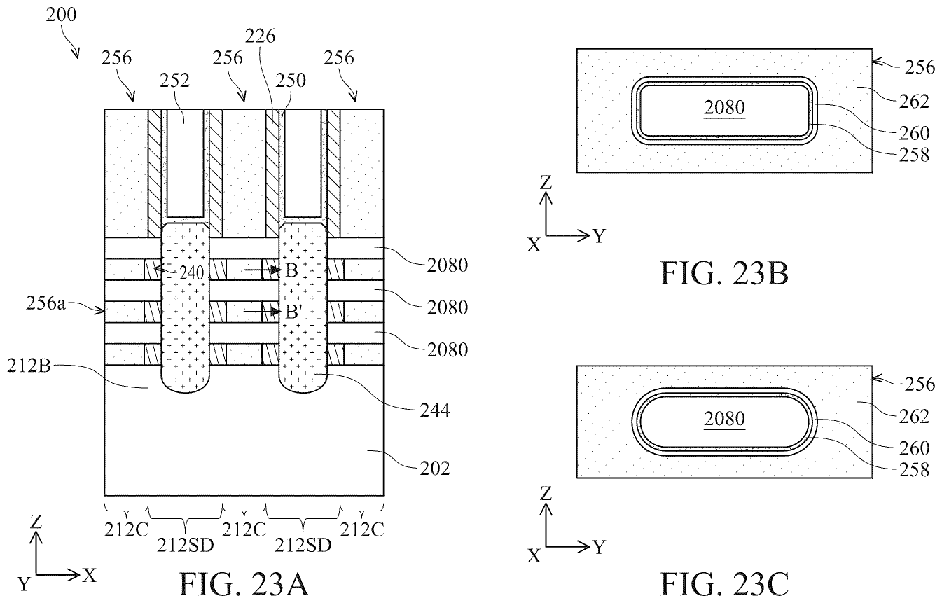

Referring to FIGS. 1 and 23A-23C, method 100 proceeds through blocks 122 and 124 as described above. FIGS. 23B and 23C illustrate enlarged cross-section views of a portion of the structure 200 taken along line B-B′ as in FIG. 23A according to different aspects of the present disclosure. FIGS. 23B and 23C represent resulted structures fabricated from structures represented by FIGS. 18B and 18C, respectively. Differences from the embodiments described with respect to FIGS. 17A-17C include the follows. As depicted in FIG. 23B, in such embodiments, the hydrogen treatment is omitted, and corners of the channel members 2080 and the base fin structure 212B are not rounded by the hydrogen treatment. The gate dielectric layer 260 and the interfacial layer 258 may have similar corner shapes as the channel layer 2080. Outer surfaces of the gate dielectric layer 260 and the interfacial layer 258 may each have a profile of a rectangle with slightly rounded corners in the cross-sectional view.

Referring to FIG. 23C, in such embodiments, the structure 200 undergoes both the hydrogen treatment 230 and the oxygen treatment 266 and is similar to the structure 200 described with respect to FIGS. 17A-17C.

For embodiments in which the structures will undergo both the hydrogen treatment 230 and the oxygen treatment 266, the oxygen treatment 266 may be performed after performing of the hydrogen treatment 230. In some embodiments, the hydrogen treatment 230 and the oxygen treatment 266 are in-situ performed, such as in a same process chamber or tool. This may avoid process-process transfer among different process chambers/tools, thus reducing manufacturing time while having the same or improved quality control. In addition, this avoids exposing the channel members 2080 and the base fin structure 212B to ambient oxygen, thus avoiding forming native oxide layers on the exposed surfaces of the channel members 2080 and the base fin structure 212B. The oxide layer 268 may have a lower uniformity value of thicknesses, a lower etching rate in a wet etching process, a higher density, and a higher silicon dioxide (SiO₂) concentration, as compared to a native oxide layer formed by exposing surfaces of the channel members 2080 and the base fin structure 212B to ambient oxygen. In such embodiments, the oxygen treatment 266 includes an oxygen plasma process as described above. In some other embodiments, the hydrogen treatment 230 and the oxygen treatment 266 are performed in different process chambers or tools. In such embodiments, the oxygen treatment 266 includes an oxygen plasma process or an annealing process as described above.

The semiconductor device 200 may undergo further processing to form various features and regions known in the art. For example, subsequent processing may form additional interlayer dielectric (ILD) layer(s), contacts/vias/lines and multilayers interconnect features (e.g., metal layers and interlayer dielectrics) over the substrate 202, configured to connect the various features to form a functional circuit that may include one or more devices including semiconductor device 200. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure.

One of ordinary skill may recognize although FIGS. 2-23C illustrate some nanosheet devices as embodiments, other examples of semiconductor devices (e.g., fork-sheet devices, to be described below with FIGS. 24-33) may benefit from aspects of the present disclosure.

Referring to FIGS. 24-25A, method 300 includes blocks 302, 304, 306 similar to blocks 102 and 104 of method 100 as described above. Differences include that, structure 400 illustrated in FIG. 25A includes fin-shaped structures 212′. The fin-shaped structures 212′ further includes a topmost sacrificial layer 206T above a topmost channel layer 208 of the fin-shaped structures 212. Differences further include that the trenches between the adjacent fin-shaped structures 212′ include first-type trenches 211 for forming isolation feature 214 therein and second-type trenches for forming center dielectric fins 420 therein. Width of the first-type trenches 211 may be greater than width of the second-type trenches (now filled by the center dielectric fins 420).

Referring to FIGS. 24-25C, method 300 includes a block 308 where the center dielectric fin 420 is formed. FIGS. 25B and 25C illustrate enlarged alternative views of a portion E of the structure 400 as in FIG. 25A. Each of the fin-shaped structures 212′ has a sidewall in contact with the center dielectric fin 420. A bottom portion of the center dielectric fin 420 may have any suitable shapes, such as a rectangle shape as depicted in FIG. 25A, a V-shape as depicted in FIG. 25B, or a U-shape as illustrated in FIG. 25C. To form the center dielectric fin 420, a first layer 416 and a second layer 418 are conformally deposited over the structure 400. The first layer 416 may be conformally deposited using CVD, ALD, or a suitable method. The first layer 416 lines the sidewalls and the bottom surfaces of the trenches between the adjacent fin-shaped structures 212′. The second layer 418 is then conformally deposited over the first layer 416 using CVD, high density plasma CVD (HDPCVD), and/or other suitable process. In some embodiments, the second layer 418 includes sub-layers formed along sidewalls of the first layer 416. The sub-layers may have an interface, such as the dashed line 419. The interface may be along a vertical center line of the center dielectric fin 420. In some embodiments, the sub-layers merge. In the following figures, the interface is not depicted, but it is understood that the second layer 418 may include the sub-layers and the sub-layers may have the interface. In some embodiments, the first layer 416 and the second layer 418 both include nitride-based dielectric material to ensure that the center dielectric fin 420 can withstand various etching operations. In some instances, the first layer 416 and the second layer 418 include silicon nitride, silicon carbonitride, silicon oxycarbonitride, aluminum nitride, aluminum oxynitride, zirconium nitride, silicon oxynitride, or a suitable dielectric material. A composition of the first layer 416 may be different from a composition of the second layer 418. In one embodiment, the first layer 416 includes an oxide material, an oxynitride material and/or silicon oxycarbonitride and the second layer 418 includes silicon carbonitride.

After the conformal deposition of the first layer 416 and the second layer 218, the deposited first layer 416 and the second layer 418 are etched back to expose the topmost sacrificial layer 206T. Due to the loading effect, the deposited first layer 416 and the second layer 418 in the wider and more accessible first-type trenches 211 as depicted are remove by the etch back process while the deposited first layer 416 and the second layer 418 in the narrower and denser second-type trench remains to become the center dielectric fin 420. In some embodiments, the first layer 416 and the second layer 418 may be etched back in a dry etch process that uses oxygen, nitrogen, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. In some implementations, the etch back may include a first stage that is directed toward the second layer 418 and a second stage that is directed toward the first layer 416. As shown in FIG. 25A, upon conclusion of the etch back, the isolation feature 214 is exposed in the trenches 211.

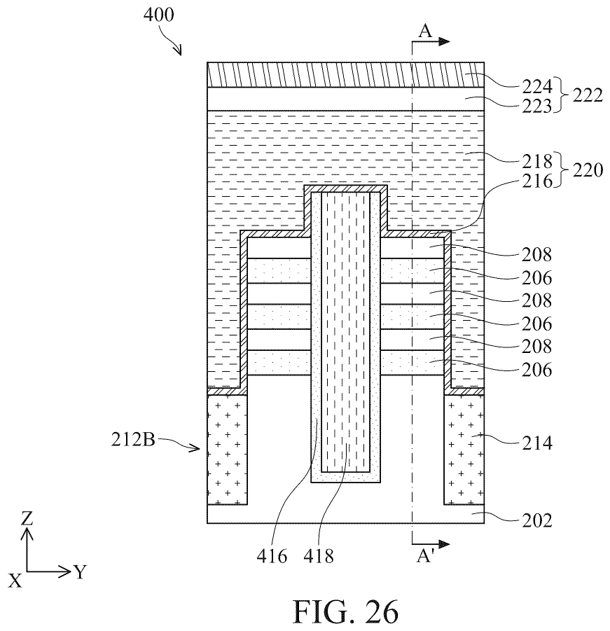

Referring to FIGS. 24 and 26, method 300 includes a block 310 where the topmost sacrificial layer 206T is removed from the fin-shaped structures 212′. At block 310, the structure 400 is etched to selectively remove the topmost sacrificial layer 206T to expose the topmost channel layer 208, without substantially damaging the center dielectric fin 420. Because the topmost sacrificial layer 206T may be formed of silicon germanium (SiGe), the etch process at block 310 may be selective to silicon germanium (SiGe). In some instances, the topmost sacrificial layer 206T may be etched using a selective wet etch process that includes ammonium hydroxide (NH₄OH), hydrogen fluoride (HF), hydrogen peroxide (H₂O₂), or a combination thereof. As shown in FIG. 26, after the removal of the topmost sacrificial layer 206T, the center dielectric fin 420 rises above the topmost channel layer 208.

Still referring to FIGS. 24 and 26, method 300 includes a block 312 where a dummy gate stack 220 is formed over the channel regions of the fin-shaped structures 212′. Operations at block 312 are similar to those at block 106. Differences from block 106 includes that the dummy gate stack 220 is also formed over the center dielectric fin 420. A fragmentary cross-sectional view of the structure 400 taken along line A-A′ as in FIG. 26 may be similar to FIG. 5.

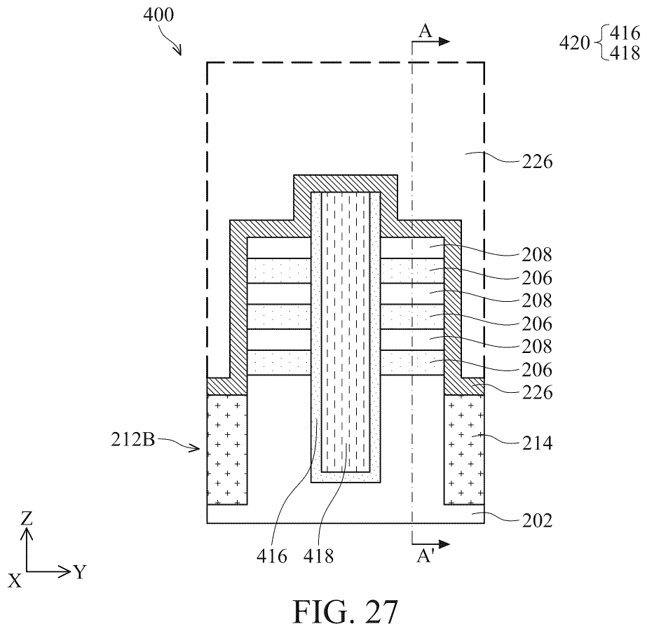

Referring to FIGS. 24 and 27, method 300 includes a block 314 where the gate spacer layer 226 is formed along sidewalls of the dummy gate stacks 220. Operations at block 314 are similar to those at block 108. One of the differences includes that the gate spacer layer 226 not only is deposited over sidewalls and top surfaces of the dummy gate stack 220 (shown in dotted lines as it is out of the plane), the isolation feature 214, and the fin-shaped structures 212′, but also is deposited over sidewalls and a top surface of the center dielectric fin 220. A fragmentary cross-sectional view of the structure 400 taken along line A-A′ as in FIG. 27 may be similar to FIG. 6.

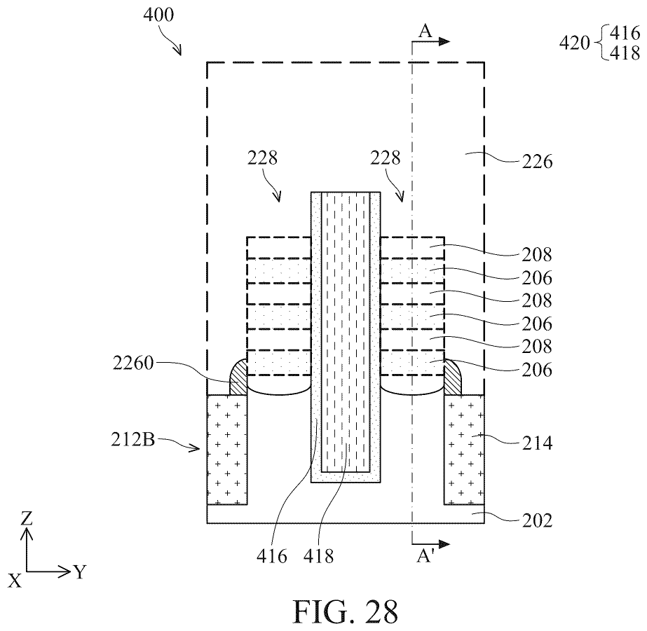

Referring to FIGS. 24 and 28, method 300 includes a block 316 where the source/drain regions of the fin-shaped structures 212′ are recessed to form source/drain recesses 228. Operations at block 316 are similar to those at block 110. As illustrated in FIG. 28, the center dielectric fin 420 in the source/drain regions remains unetched. FIG. 28 illustrates the sacrificial layers 206 and channel layers 208 under the dummy gate stack 220 in dotted lines as they are out of the illustration plane. In some embodiments represented in FIG. 28, a portion of the gate spacer layer 226 disposed along sidewalls of the fin-shaped structures 212′ may remain to form sidewalls spacers 2260. At least a lower portion of each of the fin-shaped structures 212′ is disposed between a sidewall spacer 2260 and the center dielectric fin 420 along the Y-direction. The sidewall spacers 2260 may function to control the epitaxial growth of source/drain features. A fragmentary cross-sectional view of the structure 400 taken along line A-A′ as in FIG. 28 may be similar to FIG. 7A.

Method 300 further includes operations at blocks 112 through 124 as described above. Similar as described above with respect to blocks 114A and 114B, the structure 400 may undergo the hydrogen treatment 230 and/or the oxygen treatment 266. When both the hydrogen treatment 230 and the oxygen treatment 266 are performed, the oxygen treatment 266 may be performed after performing of the hydrogen treatment 230, and the hydrogen treatment 230 and the oxygen treatment 266 may be in-situ performed, such as in a same process chamber or tool.

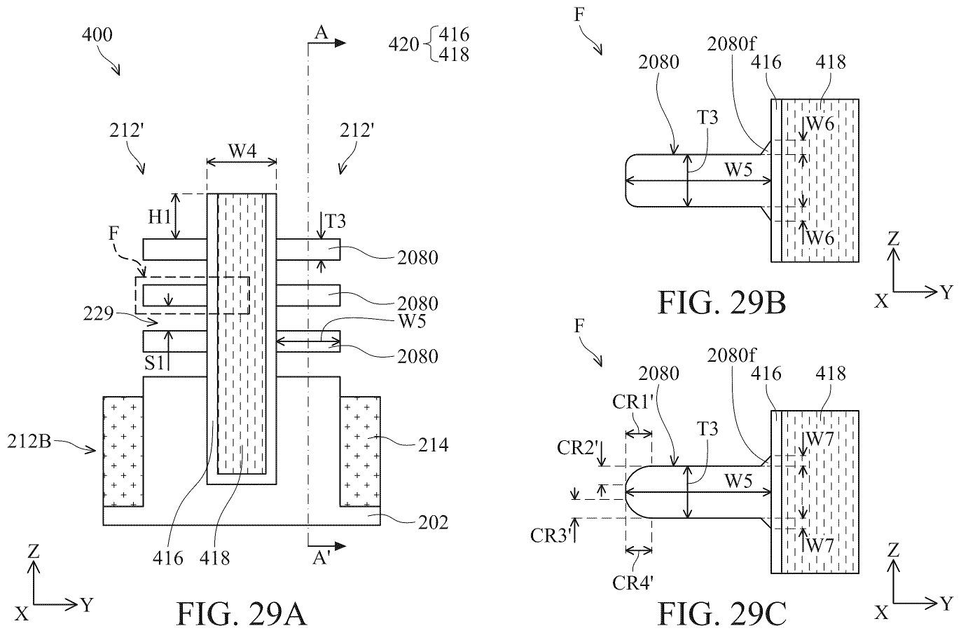

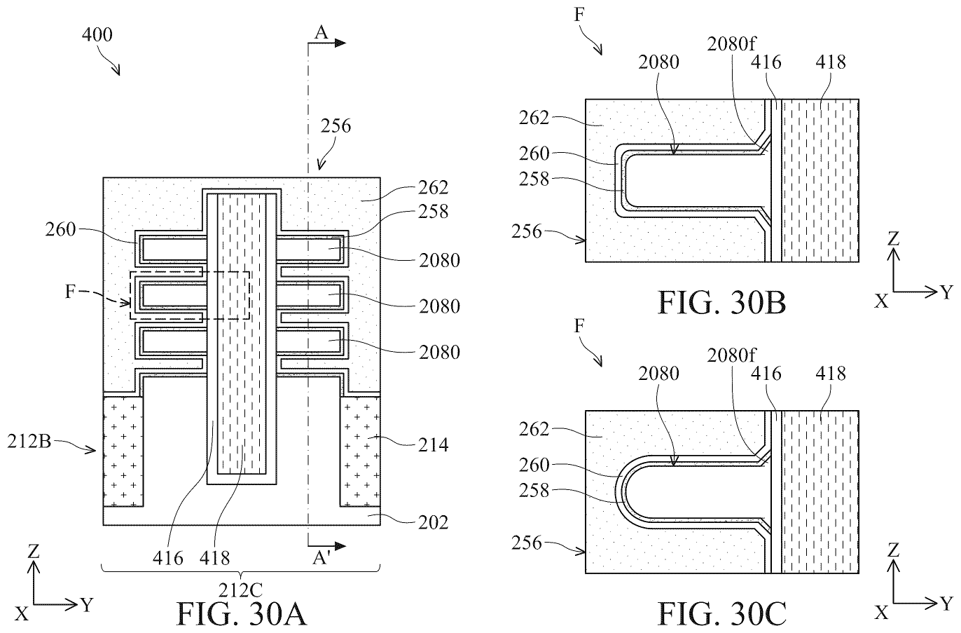

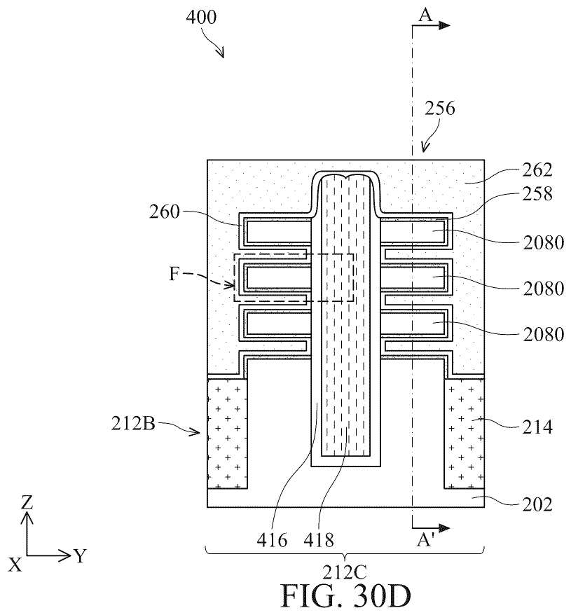

FIGS. 29A, 30A, 30D, and 31 illustrate fragmentary cross-sectional views of the structure 400 at block 124. FIGS. 29B and 29C illustrate enlarged views of a portion F of the structure 400 as in FIG. 29A according to different aspects of the present disclosure. FIGS. 30B and 30C illustrate enlarged views of a portion F of the structure 400 as in FIG. 30A or 30D according to different aspects of the present disclosure. Fragmentary cross-sectional views of the structure 400 taken along line A-A′ as in FIGS. 28, 29A, 30A, 30D, and 31 at blocks 112 through 124 may be similar to FIGS. 8A, 9A, 11-15, 17A, 18A, and 19-23A. Operations at block 124 may include removal of the dummy gate stack 220 (shown in FIGS. 29A-29C), removal of the dummy layer 236 (shown in FIGS. 29A-29C), and deposition of the gate structure 256 to wrap around each of the channel members 2080 (shown in FIGS. 30A-30D).

Referring to FIG. 29A, the spaces 229 may each have the height S1 as described above. A top surface of the center dielectric fin 420 may be higher than a top surface of a topmost channel member 2080 by a height H₁ of about 6 nm to about 10 nm. The center dielectric fin 420 may have a width W4 of about 10 nm to about 30 nm along the Y-direction. The channel members 2080 may have a width W5 of about 8 nm to about 50 nm along the Y-direction, and a thickness T3 of about 4 nm to about 8 nm along the Z-direction.

In some embodiments, referring to FIGS. 29A-29B, the hydrogen treatment has been omitted. In such embodiments, upon completion of operations at block 112, germanium residue (e.g., in residue 207′) on the channel members 2080 is negligible, instead of performing operations at block 114A, operations at block 114B are performed. In such embodiments, corners of the channel members 2080 and the base fin structure 212B are only slightly rounded in the operations at block 112 as depicted in FIG. 29B. The corner rounding dimension of the corners is less than about 2 nm, for example, about 0.5 nm to about 2 nm. A difference from FIG. 18B includes that, the structure 400 includes a center dielectric fin 420 in direct contact with the channel members 2080 of the adjacent fin-shaped structures 212′. Thus, one end of the channel member 2080 is attached to the center dielectric fin 420. In the depicted embodiment, the channel member 2080 includes footing portions 2080f on a sidewall of the center dielectric fin 420. The footing portions 2080f have a width W6, and 2*W6 (2 times of W6) is about 3 nm to about 4 nm as depicted. W6 may be along the Z-direction.

In some other embodiments, operations at block 114A and optionally operations at block 114B are performed. In such embodiments, corners of the channel members 2080 and the base fin structure 212B are rounded by the hydrogen treatment 230 as described above and depicted in FIGS. 16B and 18C. The channel member 2080 may have a corner rounding dimension (e.g., CR1′-CR4′) of about 2.5 nm to about 3.5 nm. Performing the hydrogen treatment 230 may modify (e.g., restructure) and reduce the LWR of the surfaces of the channel layers 2080 and the base fin structures 212B to about 0.3 nm to about 0.4 nm. In some embodiments, the hydrogen treatment 230 further removes at least a portion of the footing portion 2080f. The mechanisms of removing at least a portion of the footing portion 2080f may be similar to those described above with respect to the corner rounding by the hydrogen treatment 230. The footing portion 2080f may have a width W7, and 2*W7 is about 0.5 nm to about 2 nm, alternatively about 1 nm to about 2 nm along the Z-direction. W7 may be less than W6. Reduced footing portion may result in improved gate control of the channel members 2080.

Referring to FIG. 30A, a gate structure 256 is formed to wrap around each of the channel members 2080 similar to the embodiments described in FIGS. 17A and 23A. Differences include the follows. In FIG. 30A, the gate structure 256 wraps around and is disposed over the center dielectric fin 420. FIGS. 30B and 30C may correspond to FIGS. 29B and 29C, respectively. As depicted in FIGS. 30B and 30C, the gate structure 256 is disposed over the footing portions 2080f. The interfacial layer 258 and the gate dielectric layer 260 track the profile of the channel members 2080. Although not explicitly shown in the figures, subsequent processes may include formation of a dielectric gate cut feature to divide the gate structure 256 into a first portion over the stack of channel members 2080 on the left-hand side of the center dielectric fin 420 and a second portion over the stack of channel members 2080 on the right-hand side of the center dielectric fin 420. The first portion of the gate structure and the second portion of the gate structure are electrically insulated from one another. FIG. 30D illustrates an alternative view of FIG. 30A. In FIG. 30D, a difference from FIG. 30A includes that, the top portion of the center dielectric fin 420 is recessed in processes, such as the operations at blocks 112, 114A, 114B, 118, and/or 124. Top portions of the first dielectric layer 416 and/or the second dielectric layer 418 above the topmost channel members 2080 may be partially (as depicted) or fully (not depicted) removed, such as depicted. Because the second dielectric layer 418 may include the sublayers as described above, the top surface of the second dielectric layer 418 may include a dent (or a dip) in the middle as depicted.

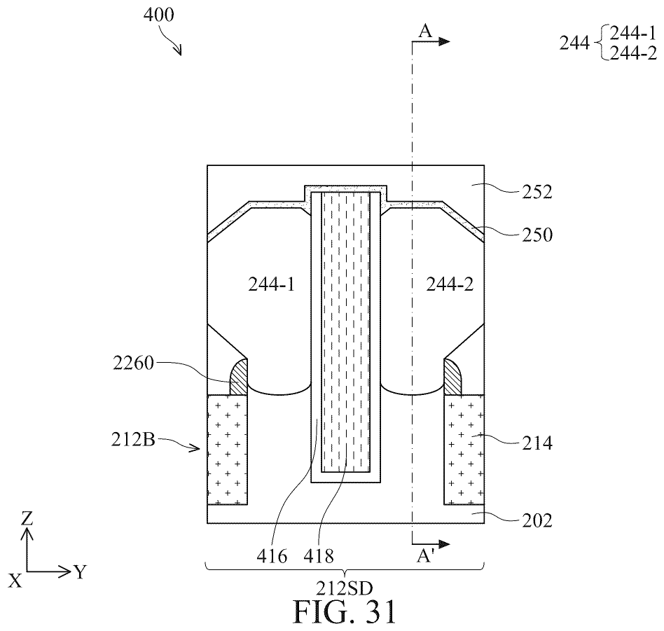

Referring to FIG. 31, a first source/drain feature 244-1 and a second source/drain feature 244-2 (may be collectively or individually referred to as the source/drain feature(s) 244)) may be selectively and epitaxially deposited on the exposed semiconductor surfaces of the channel members 2080 and the substrate 202 in the source/drain trenches 228. The first source/drain feature 244-1 and the second source/drain feature 244-2 may be formed simultaneously or in different steps. Depending on the design of the semiconductor device 400, The first source/drain feature 244-1 and the second source/drain feature 244-2 in contact with the center dielectric fin 420 may have different conductivity types. In some embodiments where a complementary metal oxide semiconductor field effect transistor (CMOSFET) is desired, one of the first source/drain feature 244-1 and the second source/drain feature 244-2 is n-type and may include silicon (Si) doped with an n-type dopant, and the other is p-type and may include silicon germanium (SiGe) doped with a p-type dopant. In some other embodiments where a n-type MOSFET (NMOSFET) is desired, both the first source/drain feature 244-1 and the second source/drain feature 244-2 are n-type. In still other embodiments where p-type MOSFET (PMOSFET) is desired, both the first source/drain feature 244-1 and the second source/drain feature 244-2 are p-type. Along the X direction, two second source/drain features 244-2 sandwich the channel members 2080 in the channel region 212C as depicted in FIGS. 17A and 23A.

The semiconductor device 400 may undergo further processing to form various features and regions known in the art. For example, subsequent processing may form additional interlayer dielectric (ILD) layer(s), contacts/vias/lines and multilayers interconnect features (e.g., metal layers and interlayer dielectrics) over the substrate 202, configured to connect the various features to form a functional circuit that may include one or more devices including semiconductor device 400. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure.

FIGS. 32-33 illustrate an alternative structure 500 made by method 300. As compared to the structure 400, differences are as follows. At block 306, the isolation features 214 are formed in both the first-type trenches 211 and the second-type trenches. At block 308, the center dielectric fin 420 is formed over the isolation feature 214 as depicted in FIGS. 32-33.

Although not intended to be limiting, one or more embodiments of the present disclosure provide many benefits to a semiconductor device. For example, the present disclosure modifies surfaces of the channel members of a transistor by performing a hydrogen treatment and/or performing an oxygen treatment to the channel members. Thus, residues of germanium are reduced or mitigated, surface roughness of the channel members are reduced, uniformity of interfaces between the channel members and the source/drain feature may be improved regardless of conductivity types of the source/drain feature, and/or channel members are protected by an oxide layer during the manufacturing process. Thus, the overall performance of the semiconductor device may be improved.

In one exemplary aspect, the present disclosure is directed to a method. The method includes providing a workpiece including a fin-shaped structure including a stack of alternating channel layers and sacrificial layers, forming a dummy gate structure over a channel region of the fin-shaped structure, forming a source/drain recess in a source/drain region of the fin-shaped structure, selectively removing the sacrificial layers in the channel region to release the channel layers as channel members, performing a hydrogen treatment to the workpiece, after performing the hydrogen treatment, depositing a dummy layer around the channel members, forming a source/drain feature over the source/drain region, and replacing the dummy gate structure and the dummy layer with a metal gate structure.

In some embodiments, the method further includes performing an oxygen treatment to the workpiece after performing the hydrogen treatment to the workpiece. In some embodiments, performing the oxygen treatment to the workpiece includes performing an annealing process with steam or performing an oxygen plasma process. In some embodiments, performing the oxygen treatment forms an oxide layer over the channel layers and the source/drain region, the dummy layer is disposed over the oxide layer, selectively and partially recessing the dummy layer includes selectively and partially recessing the oxide layer, and replacing the dummy gate structure and the dummy layer with the metal gate structure further includes removing the oxide layer before forming the metal gate structure. In some embodiments, performing the hydrogen treatment to the workpiece includes performing an annealing process with hydrogen or performing a hydrogen plasma process. In some embodiments, after performing the hydrogen treatment, the channel layers have rounded corners in a cross-sectional view. In some embodiments, the channel layers include silicon and the sacrificial layers include silicon germanium, performing the hydrogen treatment to the workpiece removes a germanium oxide layer and restructures silicon on surfaces of the channel layers. In some embodiments, the fin-shaped structure is a first fin-shaped structure, the workpiece further includes a second fin-shaped structure adjacent to the first fin-shaped structure and a dielectric fin disposed between and in contact with the first and second fin-shaped structures, and a top surface of the dielectric fin is higher than a topmost surface of the first fin-shaped structure. In some embodiments, the dielectric fin includes an oxide layer interfacing the channel layers, each channel layer of the channel layers includes a footing feature at an interface between the each channel layers and the oxide layer, and performing the hydrogen treatment reduces the footing feature. In some embodiments, the hydrogen treatment is performed at a temperature of about 300° C. to about 900° C.

In another exemplary aspect, the present disclosure is directed to a method. The method includes providing a workpiece. The workpiece includes a substrate, a stack of channel layers and sacrificial layers disposed over the substrate, and a source/drain trench adjacent to the stack and exposing sidewalls of the sacrificial layers. Compositions of the sacrificial layers and the channel layers are different, and the sacrificial layers includes silicon germanium. The method further includes performing an etching process to selectively remove the sacrificial layers. After the performing of the etching process, the channel layers contain germanium oxide. The method further includes reducing a content of the germanium oxide in the channel layers, forming a source/drain feature in the source/drain trench, and forming a gate structure wrapping around and over the channel layers.

In some embodiments, reducing the content of the germanium oxide includes performing a hydrogen treatment to the channel layers. In some embodiments, the method further includes after reducing the content of the germanium oxide, performing an oxygen treatment to the channel layers, thereby forming an oxide layer over the channel layers. In some embodiments, reducing the content of the germanium oxide and the performing of the oxygen treatment are conducted in a same process chamber. In some embodiments, reducing the content of the germanium oxide in the channel layers reduces line width roughness (LWR) of the channel layers.

In yet another exemplary aspect, the present disclosure is directed to a method. The method includes forming a stack of alternating channel layers and sacrificial layers, forming a dummy gate structure over a channel region of the stack, forming a source/drain recess in a source/drain region of the stack, selectively removing the sacrificial layers in the channel region to release the channel layers as channel members, performing an oxygen treatment, thereby forming an oxide layer over the channel members, depositing a dummy layer over the oxide layer, forming a source/drain feature over the source/drain region, and replacing the dummy gate structure, the oxide layer, and the dummy layer with a metal gate structure.

In some embodiments, performing the oxygen treatment performing an annealing process with steam or performing an oxygen plasma process. In some embodiments, performing the oxygen treatment includes using a source gas including oxygen, hydrogen, and argon. In some embodiments, the oxygen treatment is performed at a temperature of about 100° C. to about 900° C. In some embodiments, the method further includes performing a hydrogen treatment before performing the oxygen treatment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
providing a workpiece including a fin-shaped structure including a stack of alternating channel layers and sacrificial layers;
forming a dummy gate structure over a channel region of the fin-shaped structure;
forming a source/drain recess in a source/drain region of the fin-shaped structure;
selectively removing the sacrificial layers in the channel region to release the channel layers as channel members;
performing a hydrogen treatment to the workpiece;
after performing the hydrogen treatment, depositing a dummy layer around the channel members;
forming a source/drain feature over the source/drain region; and
replacing the dummy gate structure and the dummy layer with a metal gate structure.

2. The method of claim 1, further comprising performing an oxygen treatment to the workpiece after performing the hydrogen treatment to the workpiece.

3. The method of claim 2, wherein performing the oxygen treatment to the workpiece includes performing an annealing process with steam or performing an oxygen plasma process.

4. The method of claim 2, wherein performing the oxygen treatment forms an oxide layer over the channel layers and the source/drain region,
wherein the dummy layer is disposed over the oxide layer,
wherein selectively and partially recessing the dummy layer includes selectively and partially recessing the oxide layer, and
wherein replacing the dummy gate structure and the dummy layer with the metal gate structure further includes removing the oxide layer before forming the metal gate structure.

5. The method of claim 1, wherein performing the hydrogen treatment to the workpiece includes performing an annealing process with hydrogen or performing a hydrogen plasma process.

6. The method of claim 1, wherein after performing the hydrogen treatment, the channel layers have rounded corners in a cross-sectional view.

7. The method of claim 1, wherein the channel layers include silicon and the sacrificial layers include silicon germanium,
wherein performing the hydrogen treatment to the workpiece removes a germanium oxide layer and restructures silicon on surfaces of the channel layers.

8. The method of claim 1, wherein the fin-shaped structure is a first fin-shaped structure,
wherein the workpiece further includes a second fin-shaped structure adjacent to the first fin-shaped structure and a dielectric fin disposed between and in contact with the first and second fin-shaped structures, and
wherein a top surface of the dielectric fin is higher than a topmost surface of the first fin-shaped structure.

9. The method of claim 8, wherein the dielectric fin includes an oxide layer interfacing the channel layers,
wherein each channel layer of the channel layers includes a footing feature at an interface between the each channel layers and the oxide layer, and
wherein performing the hydrogen treatment reduces the footing feature.

10. The method of claim 1, wherein the hydrogen treatment is performed at a temperature of about 300° C. to about 900° C.

11. A method, comprising:
providing a workpiece including:
a substrate,
a stack of channel layers and sacrificial layers disposed over the substrate, wherein compositions of the sacrificial layers and the channel layers are different, and the sacrificial layers includes silicon germanium, and
a source/drain trench adjacent to the stack and exposing sidewalls of the sacrificial layers;
performing an etching process to selectively remove the sacrificial layers, wherein, after the performing of the etching process, the channel layers contain germanium oxide;
reducing a content of the germanium oxide in the channel layers;
forming a source/drain feature in the source/drain trench; and
forming a gate structure wrapping around and over the channel layers.

12. The method of claim 11, wherein reducing the content of the germanium oxide includes performing a hydrogen treatment to the channel layers.

13. The method of claim 11, further comprising:
after reducing the content of the germanium oxide, performing an oxygen treatment to the channel layers, thereby forming an oxide layer over the channel layers.

14. The method of claim 13, wherein reducing the content of the germanium oxide and the performing of the oxygen treatment are conducted in a same process chamber.

15. The method of claim 11, wherein reducing the content of the germanium oxide in the channel layers reduces line width roughness (LWR) of the channel layers.

16. A method, comprising:
forming a stack of alternating channel layers and sacrificial layers;
forming a dummy gate structure over a channel region of the stack;
forming a source/drain recess in a source/drain region of the stack;
selectively removing the sacrificial layers in the channel region to release the channel layers as channel members;
performing an oxygen treatment, thereby forming an oxide layer over the channel members;
depositing a dummy layer over the oxide layer;
forming a source/drain feature over the source/drain region; and
replacing the dummy gate structure, the oxide layer, and the dummy layer with a metal gate structure.

17. The method of claim 16, wherein performing the oxygen treatment performing an annealing process with steam or performing an oxygen plasma process.

18. The method of claim 16, wherein performing the oxygen treatment includes using a source gas including oxygen, hydrogen, and argon.

19. The method of claim 16, wherein the oxygen treatment is performed at a temperature of about 100° C. to about 900° C.

20. The method of claim 16, further comprising performing a hydrogen treatment before performing the oxygen treatment.
